(19) United States
(12) Patent Application Publication
(10) Pub. No.: US 2015/0287746 A1
(43) Pub. Date: Oct. 8, 2015

(54) METHOD OF MANUFACTURING SEMICONDUCTOR DEVICE, AND SEMICONDUCTOR DEVICE

(71) Applicant: RENESAS ELECTRONICS CORPORATION, Kawasaki-shi (JP)

(72) Inventors: Hiroki SHINKAWATA, Kawasaki-shi (JP); Toshiaki IWAMATSU, Kawasaki-shi (JP)

(21) Appl. No.: 14/674,838

(22) Filed: Mar. 31, 2015

(30) Foreign Application Priority Data
Apr. 3, 2014 (JP) 2014-076974

(51) Int. Cl. H01L 27/12; H01L 21/8234; H01L 29/06; H01L 21/762; H01L 21/027; H01L 29/167; H01L 21/84; H01L 29/66

(52) U.S. Cl. CPC H01L 27/1207; H01L 21/84; H01L 21/823437; H01L 29/66545; H01L 21/7624; H01L 21/0271; H01L 29/167; H01L 29/0649

(57) ABSTRACT

In a step F2, an isolation region and an element formation region are formed in an SOI substrate. In a step F3, an SOI region and a bulk region are formed. Here, an isolation insulating film of the isolation region is exposed along the entire perimeter of a sidewall of a step between the SOI region and the bulk region. In a step F4, a gate electrode is formed. In a step F5, extension implantation of a bulk transistor is carried out. Here, treatment for preventing an impurity for extension implantation from being implanted into the SOI region is performed. In a step F6, an elevated epitaxial layer is formed in the SOI region.

### BACKGROUND OF THE INVENTION

1. Field of the Invention

The present invention relates to a method of manufacturing a semiconductor device and to a semiconductor device, and can suitably be made use of for a method of manufacturing a semiconductor device for forming an SOI region and a bulk region by applying an SOI substrate and for a semiconductor device.

2. Description of the Background Art

In order to achieve a higher speed and lowering in power consumption in a semiconductor device, a silicon on insulator (SOI) substrate has been employed as a substrate. In an SOI substrate, a silicon layer is formed on a silicon substrate with a buried oxide film called Buried OXide (BOX) being interposed.

With the use of such an SOI substrate, a semiconductor device on which a semiconductor element formed on an SOI substrate and a semiconductor element normally formed on a bulk substrate are both mounted has currently been developed. In a semiconductor device of such a type, a silicon substrate is exposed by allowing a silicon layer and a buried oxide film located in a prescribed region in the SOI substrate to remain and removing a silicon layer and a buried oxide film located in another region.

The exposed region of the silicon substrate is defined as a bulk region, in which a semiconductor element such as a bulk transistor is formed. On the other hand, such a remaining region as the silicon layer is defined as the SOI region, in which a semiconductor element such as an SOI transistor is formed. In particular, in order to lower parasitic resistance in a source-drain region in the SOI transistor, an epitaxial layer is selectively stacked on a surface of the silicon layer located in a region where the source-drain region is to be formed. Such an epitaxial layer is referred to as an elevated epitaxial layer.

For example, Japanese Patent Laying-Open No. 2013-93516 and Japanese Patent Laying-Open No. 2013-84766 are exemplary patent documents disclosing such a semiconductor device including an SOI region and a bulk region.

### SUMMARY OF THE INVENTION

Conventional semiconductor devices, however, have suffered the following problems. By forming an SOI region and a bulk region with the use of an SOI substrate, a step corresponding to a thickness of a silicon layer and a buried oxide film is produced at a boundary between the SOI region and the bulk region, and the silicon layer and the buried oxide film are exposed at a sidewall of the step.

In addition, in a process for implanting an impurity for forming an impurity region (an extension region) of a bulk transistor which is performed before formation of the elevated epitaxial layer, the impurity is also implanted into a part of the silicon layer located in the SOI region, and the silicon layer may become amorphous.

Therefore, an epitaxial layer may abnormally grow on a surface of the silicon layer exposed at the sidewall of the step in formation of the elevated epitaxial layer. Furthermore, the epitaxial layer may abnormally grow also on a surface of the amorphous silicon layer.

Other objects and novel features will become more apparent from the description herein and accompanying drawings.

According to one embodiment, processes of forming an isolation region in a substrate portion having a semiconductor layer formed on a surface of a semiconductor substrate with an insulating layer being interposed, defining a first region and a second region adjacent to each other with respect to the substrate and forming a first element formation region and a first dummy element formation region in the first region and forming a second element formation region and a second dummy element formation region in the second region by exposing the semiconductor substrate and the isolation region by allowing the semiconductor layer and the insulating layer located in the first region to remain and removing the semiconductor layer and the insulating layer located in the second region, forming a cover portion covering the first element formation region and the first dummy element formation region, introducing an impurity of one conductivity type into the second element formation region with the cover portion serving as a mask after the cover portion is formed, and forming an elevated epitaxial layer in the first element formation region with an epitaxial growth method are provided. In the process of forming an isolation region, the isolation region is formed such that the isolation region is exposed along the entire step formed at a boundary between the first region and the second region by removing the semiconductor layer and the insulating layer located in the second region.

According to another embodiment, an isolation region formed in a substrate portion including a semiconductor substrate and a semiconductor layer formed on the semiconductor substrate with an insulating layer being interposed, a first region and a second region formed in the substrate portion to be adjacent to each other, a first element formation region and a first dummy element formation region defined in the first region by the isolation region, a second element formation region and a second dummy element formation region defined in the second region by the isolation region, and an elevated epitaxial layer formed in the first element formation region are provided. In the first region, the first element formation region and the first dummy element formation region are formed in the semiconductor layer. In the second region, the second element formation region and the second dummy element formation region are formed in the semiconductor substrate. A step corresponding to a thickness of the insulating layer and the semiconductor layer is formed at a boundary between the first region and the second region. The isolation region is located to surround the first region along the entire perimeter of the step.

According to one embodiment, abnormal growth of an epitaxial layer can be suppressed.

According to another embodiment, abnormal growth of an epitaxial layer can be suppressed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart showing overview of a method of manufacturing a semiconductor device according to each embodiment.

FIG. 2 is a cross-sectional view showing one process in a method of manufacturing a semiconductor device according to a first embodiment.

FIG. 3 is a plan view showing a process performed after the process shown in FIG. 2 in the first embodiment.

FIG. 4 is a cross-sectional view along the line IV-IV shown in FIG. 3 in the first embodiment.

FIG. 5 is a plan view showing a process performed after the process shown in FIGS. 3 and 4 in the first embodiment.

FIG. 6 is a cross-sectional view along the line VI-VI shown in FIG. 5 in the first embodiment.

FIG. 7 is a plan view showing a process performed after the process shown in FIGS. 5 and 6 in the first embodiment.

FIG. 8 is a cross-sectional view along the line VIII-VIII shown in FIG. 7 in the first embodiment.

FIG. 9 is a plan view showing a process performed after the process shown in FIGS. 7 and 8 in the first embodiment.

FIG. 10 is a cross-sectional view along the line X-X shown in FIG. 9 in the first embodiment.

FIG. 11 is a plan view showing a process performed after the process shown in FIGS. 9 and 10 in the first embodiment.

FIG. 12 is a cross-sectional view along the line XII-XII shown in FIG. 11 in the first embodiment.

FIG. 13 is a cross-sectional view showing a process performed after the process shown in FIGS. 11 and 12 in the first embodiment.

FIG. 14 is a cross-sectional view showing a process performed after the process shown in FIG. 13 in the first embodiment.

FIG. 15 is a plan view showing a process performed after the process shown in FIG. 14 in the first embodiment.

FIG. 16 is a cross-sectional view along the line XVI-XVI shown in FIG. 15 in the first embodiment.

FIG. 17 is a cross-sectional view showing a process performed after the process shown in FIGS. 15 and 16 in the first embodiment.

FIG. 18 is a cross-sectional view showing a process performed after the process shown in FIG. 17 in the first embodiment.

FIG. 19 is a cross-sectional view showing a process performed after the process shown in FIG. 18 in the first embodiment.

FIG. 20 is a plan view showing a process performed after the process shown in FIG. 19 in the first embodiment.

FIG. 21 is a cross-sectional view along the line XXI-XXI shown in FIG. 20 in the first embodiment.

FIG. 22 is a cross-sectional view showing a process performed after the process shown in FIGS. 20 and 21 in the first embodiment.

FIG. 23 is a cross-sectional view showing a process performed after the process shown in FIG. 22 in the first embodiment.

FIG. 24 is a cross-sectional view showing a process performed after the process shown in FIG. 23 in the first embodiment.

FIG. 25 is a cross-sectional view showing a process performed after the process shown in FIG. 24 in the first embodiment.

FIG. 26 is a cross-sectional view showing a process performed after the process shown in FIG. 25 in the first embodiment.

FIG. 27 is a cross-sectional view showing a process performed after the process shown in FIG. 26 in the first embodiment.

FIG. 28 is a cross-sectional view showing a process performed after the process shown in FIG. 27 in the first embodiment.

FIG. 29 is a cross-sectional view showing a process performed after the process shown in FIG. 28 in the first embodiment.

FIG. 30 is a cross-sectional view showing a process performed after the process shown in FIG. 29 in the first embodiment.

FIG. 31 is a plan view showing one process in a method of manufacturing a semiconductor device according to a comparative example.

FIG. 32 is a cross-sectional view along the line XXXII-XXXII shown in FIG. 31.

FIG. 33 is a plan view showing a process performed after the process shown in FIGS. 31 and 32.

FIG. 34 is a cross-sectional view along the line XXXIV-XXXIV shown in FIG. 33.

FIG. 35 is a plan view showing a process performed after the process shown in FIGS. 33 and 34.

FIG. 36 is a cross-sectional view along the line XXXVI-XXXVI shown in FIG. 35.

FIG. 37 is a plan view showing a process performed after the process shown in FIGS. 35 and 36.

FIG. 38 is a cross-sectional view along the line XXXVIII-XXXVIII shown in FIG. 37.

FIG. 39 is a plan view showing a process performed after the process shown in FIGS. 37 and 38.

FIG. 40 is a cross-sectional view along the line XL-XL shown in FIG. 39.

FIG. 41 is a cross-sectional view showing a process performed after the process shown in FIGS. 39 and 40.

FIG. 42 is a plan view showing a process performed after the process shown in FIG. 41.

FIG. 43 is a cross-sectional view along the line XLIII-XLIII shown in FIG. 42.

FIG. 44 is a cross-sectional view showing a process performed after the process shown in FIGS. 42 and 43.

FIG. 45 is a cross-sectional view for illustrating a problem of a semiconductor device according to the comparative example.

FIG. 46 is a plan view showing one process in a method of manufacturing a semiconductor device according to a second embodiment.

FIG. 47 is a cross-sectional view along the line XLVII-XLVII shown in FIG. 46 in the second embodiment.

FIG. 48 is a plan view showing a process performed after the process shown in FIGS. 46 and 47 in the second embodiment.

FIG. 49 is a cross-sectional view along the line XLIX-XLIX shown in FIG. 48 in the second embodiment.

FIG. 50 is a plan view showing a process performed after the process shown in FIGS. 48 and 49 in the second embodiment.

FIG. 51 is a cross-sectional view along the line LI-LI shown in FIG. 50 in the second embodiment.

FIG. 52 is a plan view showing a process performed after the process shown in FIGS. 50 and 51 in the second embodiment.

FIG. 53 is a cross-sectional view along the line LIII-LIII shown in FIG. 52 in the second embodiment.

FIG. 54 is a cross-sectional view showing a process performed after the process shown in FIGS. 52 and 53 in the second embodiment.

FIG. 55 is a plan view showing a process performed after the process shown in FIG. 54 in the second embodiment.

FIG. 56 is a cross-sectional view along the line LVI-LVI shown in FIG. 55 in the second embodiment.

FIG. 57 is a cross-sectional view showing a process performed after the process shown in FIGS. 55 and 56 in the second embodiment.

FIG. 58 is a cross-sectional view showing a process performed after the process shown in FIG. 57 in the second embodiment.

FIG. 59 is a cross-sectional view showing a process performed after the process shown in FIG. 58 in the second embodiment.

FIG. 60 is a plan view showing one process in a method of manufacturing a semiconductor device according to a third embodiment.

FIG. 61 is a cross-sectional view along the line LXI-LXI shown in FIG. 60 in the third embodiment.

FIG. 62 is a plan view showing a process performed after the process shown in FIGS. 60 and 61 in the third embodiment.

FIG. 63 is a cross-sectional view along the line LXIII-LXIII shown in FIG. 62 in the third embodiment.

FIG. 64 is a plan view showing a process performed after the process shown in FIGS. 62 and 63 in the third embodiment.

FIG. 65 is a cross-sectional view along the line LXV-LXV shown in FIG. 64 in the third embodiment.

FIG. 66 is a plan view showing a process performed after the process shown in FIGS. 64 and 65 in the third embodiment.

FIG. 67 is a cross-sectional view along the line LXVII-LXVII shown in FIG. 66 in the third embodiment.

FIG. 68 is a cross-sectional view showing a process performed after the process shown in FIGS. 66 and 67 in the third embodiment.

FIG. 69 is a cross-sectional view showing a process performed after the process shown in FIG. 68 in the third embodiment.

FIG. 70 is a plan view showing a process performed after the process shown in FIG. 69 in the third embodiment.

FIG. 71 is a cross-sectional view along the line LXXI-LXXI shown in FIG. 70 in the third embodiment.

FIG. 72 is a cross-sectional view showing a process performed after the process shown in FIGS. 70 and 71 in the third embodiment.

FIG. 73 is a cross-sectional view showing a process performed after the process shown in FIG. 72 in the third embodiment.

FIG. 74 is a cross-sectional view showing a process performed after the process shown in FIG. 73 in the third embodiment.

FIG. 75 is a cross-sectional view showing a process performed after the process shown in FIG. 74 in the third embodiment.

FIG. 76 is a cross-sectional view showing a process performed after the process shown in FIG. 75 in the third embodiment.

FIG. 77 is a cross-sectional view showing a process performed after the process shown in FIG. 76 in the third embodiment.

FIG. 78 is a flowchart showing a method of creating a pattern for not allowing arrangement of a dummy element formation region and a dummy gate electrode at a boundary of an SOI region according to a fourth embodiment.

FIG. 79 is a diagram showing an SOI region pattern, a dummy element formation region pattern, and a dummy gate electrode pattern in an initial state on the same plane in the fourth embodiment.

FIG. 80 is a diagram showing the SOI region pattern in the fourth embodiment.

FIG. 81 is a diagram showing one step for illustrating a technique for excluding the dummy element formation region pattern located at the boundary of the SOI region from the dummy element formation region pattern in the initial state in the fourth embodiment.

FIG. 82 is a diagram showing a step performed after the step shown in FIG. 81 in the fourth embodiment.

FIG. 83 is a diagram showing a step performed after the step shown in FIG. 82 in the fourth embodiment.

FIG. 84 is a diagram showing a step performed after the step shown in FIG. 83 in the fourth embodiment.

FIG. 85 is a diagram showing one step for illustrating a technique for excluding the dummy gate electrode pattern located at the boundary of the SOI region from the dummy gate electrode pattern in the initial state in the fourth embodiment.

FIG. 86 is a diagram showing a step performed after the step shown in FIG. 85 in the fourth embodiment.

FIG. 87 is a diagram showing a step performed after the step shown in FIG. 86 in the fourth embodiment.

FIG. 88 is a diagram showing a step performed after the step shown in FIG. 87 in the fourth embodiment.

FIG. 89 is a diagram showing the dummy element formation region pattern shown in FIG. 84 and the dummy gate electrode pattern shown in FIG. 88 on the same plane in the fourth embodiment.

FIG. 90 is a flowchart showing a method of creating a pattern by excluding the SOI region pattern from an implantation dummy region pattern in the fourth embodiment.

FIG. 91 is a diagram showing one step for illustrating a technique for excluding the SOI region pattern from the implantation dummy region pattern in the initial state in the fourth embodiment.

### DESCRIPTION OF THE PREFERRED EMBODIMENTS

Initially, overview of a method of manufacturing a semiconductor device including an SOI region and a bulk region will be described.

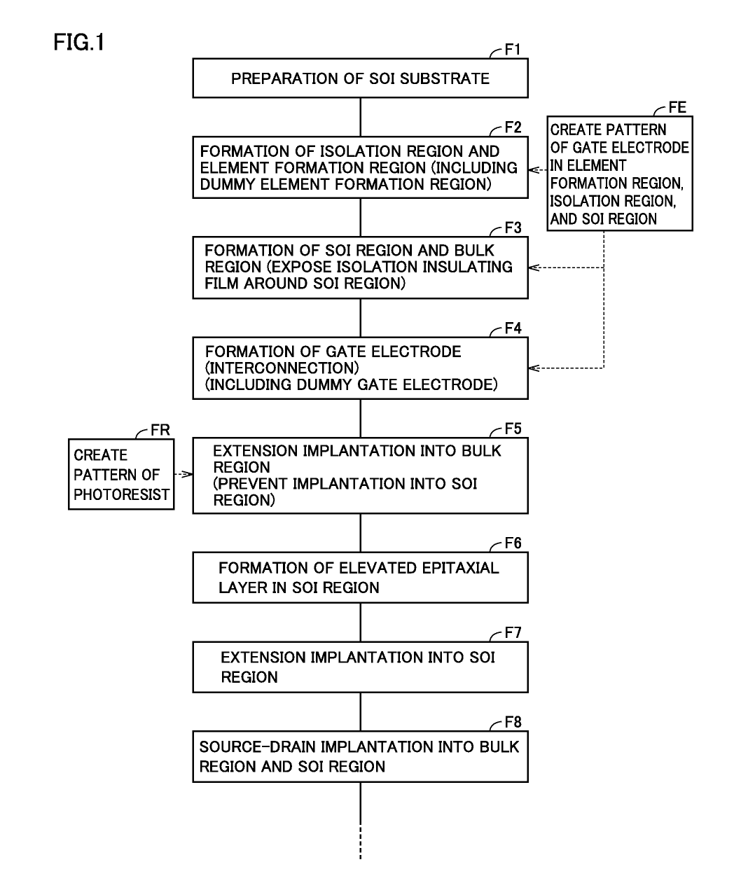

As shown in FIG. 1, initially, in a step F1, an SOI substrate (a substrate portion) is prepared. Then, in a step F2, an isolation region and an element formation region are formed. The isolation region defines the element formation region. The element formation region includes a dummy element formation region. Then, in a step F3, an SOI region and a bulk region are formed through photolithography and etching treatment onto the SOI substrate. Here, an isolation insulating film of the isolation region is exposed along the entire perimeter of a sidewall of a step between the SOI region and the bulk region.

Then, in a step F4, a gate electrode (interconnection) is formed. The gate electrode includes a dummy gate electrode. Then, in a step F5, extension implantation for forming an extension region of a bulk transistor formed in a bulk region is carried out. Here, treatment for preventing an impurity for extension implantation from being implanted into the SOI region is performed in advance. Then, in a step F6, an elevated epitaxial layer is formed in the SOI region.

Then, in a step F7, extension implantation for forming an extension region of an SOI transistor formed in the SOI region is carried out. Then, in a step F8, source-drain implantation for forming a source-drain region of each of a bulk transistor and an SOI transistor is carried out. Thus, the bulk transistor is formed in the bulk region and the SOI transistor is formed in the SOI region. Thereafter, an interlayer insulating film and an interconnection are formed, and thus a main portion of a semiconductor device is formed.

In this series of manufacturing processes, in particular in step F2, step F3, and step F4, a pattern (a mask pattern) of an element formation region and a gate electrode is created in advance in a step FE such that a dummy element formation region and a dummy gate electrode are not arranged at a boundary between the SOI region and the bulk region. In addition, in step F5, a pattern (a mask pattern) of a photoresist preventing implantation is created in advance in a step FR such that an impurity for extension implantation is not implanted into the SOI region.

In the method of manufacturing a semiconductor device described above, in forming the SOI region and the bulk region, an isolation insulating film of the isolation region is exposed along the entire perimeter of the sidewall of the step between the SOI region and the bulk region. Thus, abnormal growth of an epitaxial layer in the SOI region during formation of an elevated epitaxial layer can be suppressed.

In addition, abnormal growth of an epitaxial layer in the SOI region can be suppressed by forming a resist pattern so as to cover the SOI region such that an impurity for extension implantation is not implanted into the SOI region during extension implantation into the bulk region. Furthermore, abnormal growth of an epitaxial layer in the SOI region can be suppressed by forming a dummy gate electrode so as to cover the dummy element formation region arranged in the SOI region. Moreover, abnormal growth of an epitaxial layer in the SOI region can be suppressed by forming a dummy gate electrode and a sidewall protection film so as to cover the dummy element formation region arranged in the SOI region. A process for manufacturing a semiconductor device will specifically be described below in each embodiment.

### First Embodiment

Here, a technique for exposing an isolation insulating film of an isolation region along the entire perimeter of a sidewall of a step between an SOI region and a bulk region and then forming a resist pattern so as to cover the SOI region in extension implantation into the bulk region will be described.

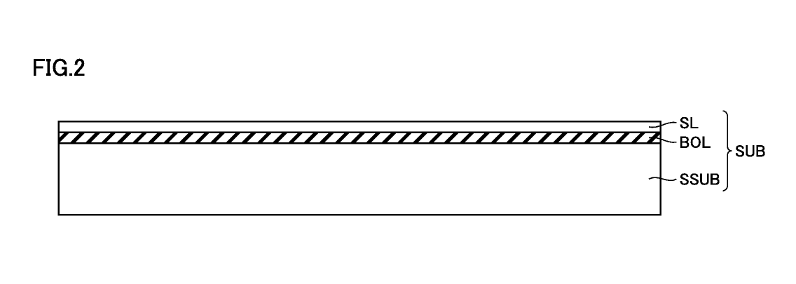

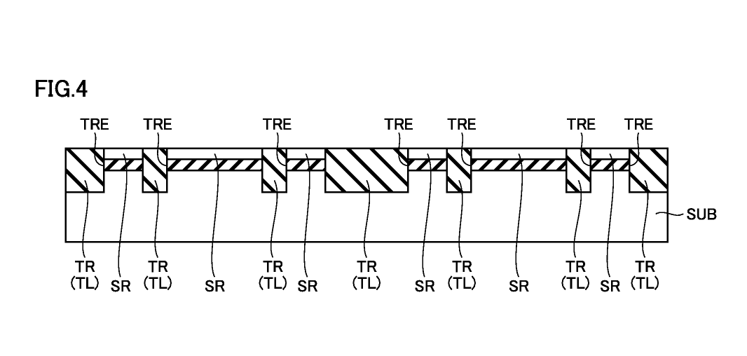

Initially, as shown in FIG. 2, an SOI substrate SUB is prepared. In SOI substrate SUB, for example, a silicon layer SL is formed on a silicon substrate SSUB with a buried oxide film BOL being interposed. Then, a trench isolation groove TRE (see FIG. 4) for forming the isolation region is formed through prescribed photolithography and etching treatment. Then, an insulating film (not shown) such as a silicon oxide film is formed on SOI substrate SUB so as to bury trench isolation groove TRE.

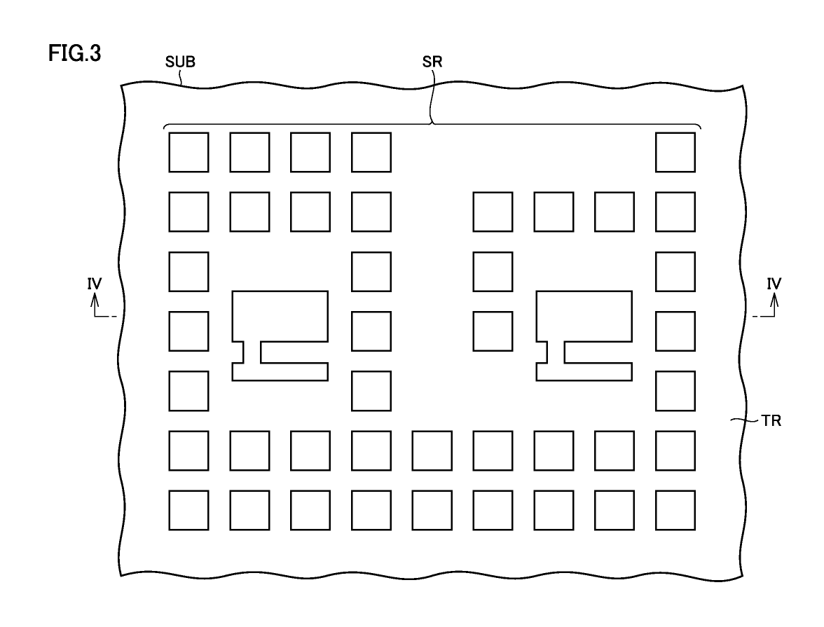

Then, for example, by removing a portion of the insulating film located on an upper surface of SOI substrate SUB through chemical mechanical polishing treatment, as shown in FIGS. 3 and 4, a portion of the insulating film located within trench isolation groove TRE remains as a trench isolation insulating film TL and an isolation region TR is formed. Isolation region TR defines an element formation region SR (an active region). As will be described later, element formation region SR includes an element formation region where a prescribed semiconductor element such as a bulk transistor or an SOI transistor is to be formed and a dummy element formation region.

Here, a pattern not allowing arrangement of an element formation region is set (defined) at the boundary between the SOI region and the bulk region as a pattern of element formation region SR (isolation region TR). A technique for creating this pattern will be described in a last embodiment.

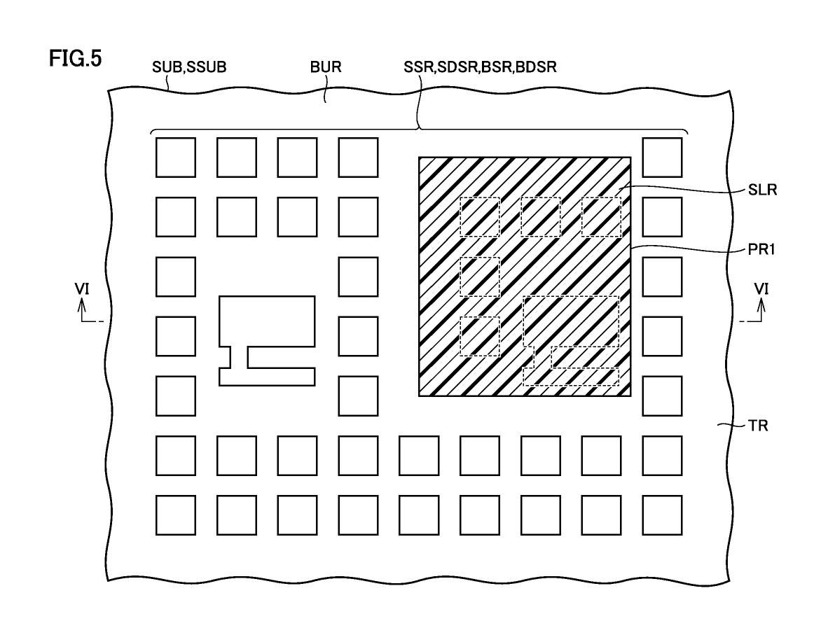

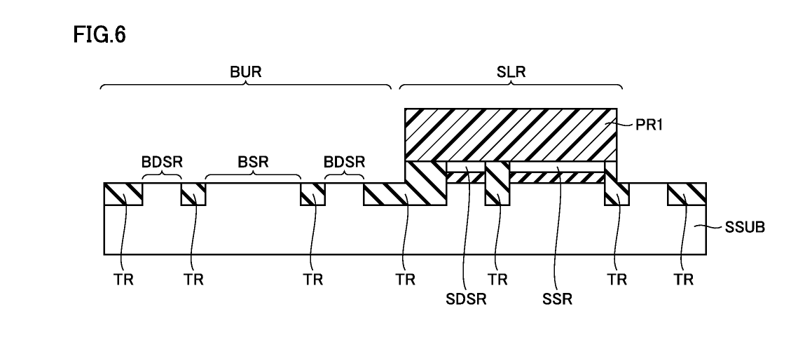

Then, the SOI region and the bulk region are formed. As shown in FIGS. 5 and 6, a photoresist PR1 is formed on a region where the SOI region is to be arranged through prescribed photolithography. Then, through etching treatment onto an exposed region of SOI substrate SUB with photoresist PR1 serving as an etching mask, silicon layer SL and buried oxide film BOL are removed, and a bulk region BUR where a surface of silicon substrate SSUB is exposed is formed.

In bulk region BUR, remaining isolation region TR defines an element formation region BSR where a semiconductor element such as a bulk transistor is to be formed and a dummy element formation region BDSR. On the other hand, a portion of SOI substrate SUB which has remained without being etched serves as an SOI region SLR. In SOI region SLR, isolation region TR defines an element formation region SSR where a semiconductor element such as an SOI transistor is to be formed and a dummy element formation region SDSR. Thereafter, photoresist PR1 is removed.

Then, a gate electrode (a gate interconnection) is formed. The gate electrode includes a gate electrode and a dummy gate electrode of each of the SOI transistor and the bulk transistor. As a pattern of the gate electrode, a pattern not allowing arrangement of a gate electrode is set (defined) at the boundary between the SOI region and the bulk region. A technique for creating this pattern will be described in the last embodiment.

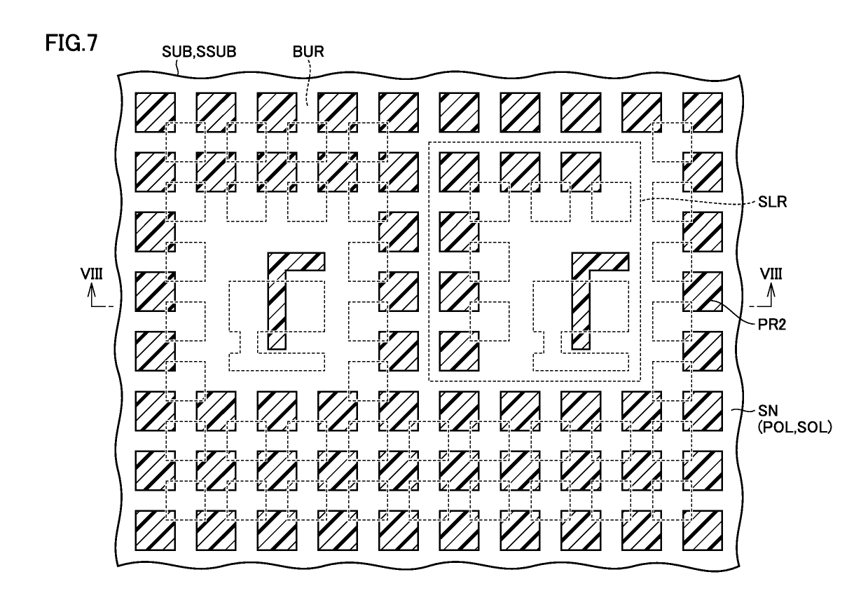

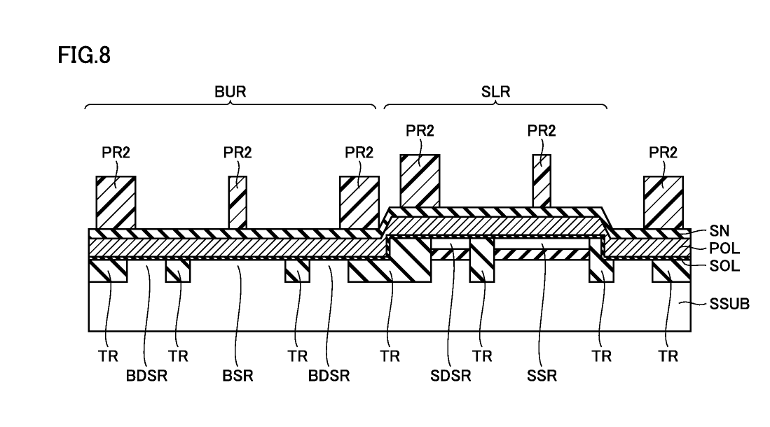

As shown in FIGS. 7 and 8, a silicon oxide film SOL is formed through thermal oxidation treatment. A polysilicon film POL is formed, for example, through a chemical vapor deposition method so as to cover silicon oxide film SOL. A silicon nitride film SN is formed to cover polysilicon film POL. A photoresist PR2 for patterning a gate electrode is formed through prescribed photolithography.

Then, a hard mask for patterning a gate electrode is formed through etching treatment onto exposed silicon nitride film SN with photoresist PR2 serving as an etching mask. A gate electrode is formed through etching treatment with the hard mask serving as an etching mask. Thereafter, photoresist PR2 is removed.

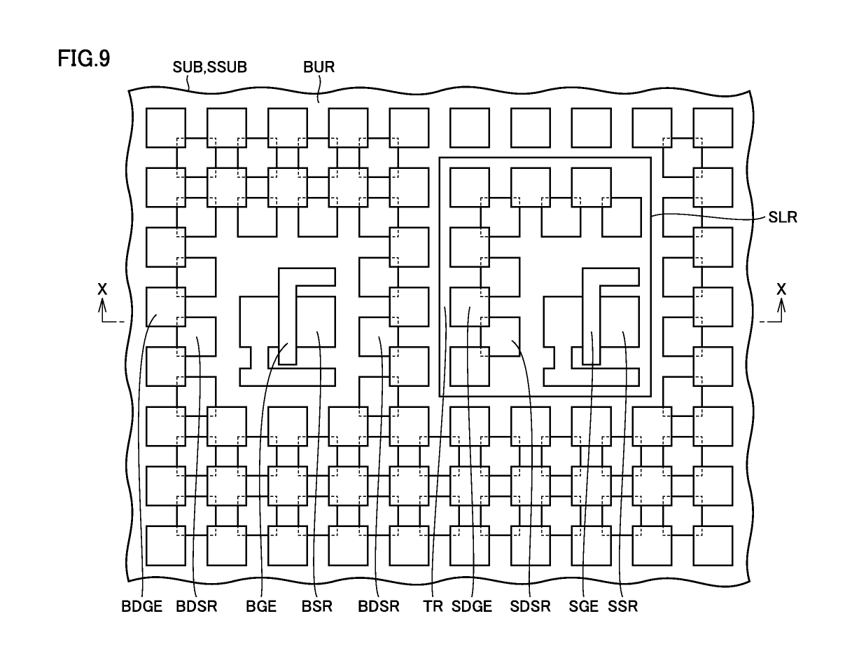

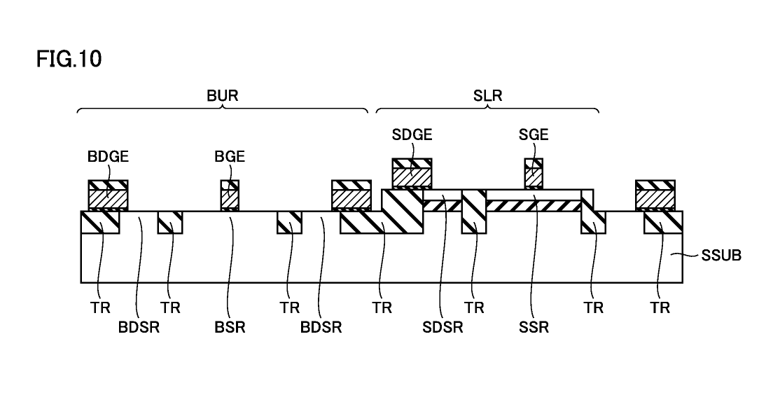

Thus, as shown in FIGS. 9 and 10, a gate electrode SGE and a dummy gate electrode SDGE are formed in SOI region SLR. Gate electrode SGE of the SOI transistor is arranged to extend across element formation region SSR. In bulk region BUR, a gate electrode BGE and a dummy gate electrode BDGE are formed. Gate electrode BGE of the bulk transistor is arranged to extend across element formation region BSR.

Then, extension implantation of the bulk transistor is carried out. Here, description will be given, assuming an n-channel type bulk transistor as a bulk transistor shown in the drawings.

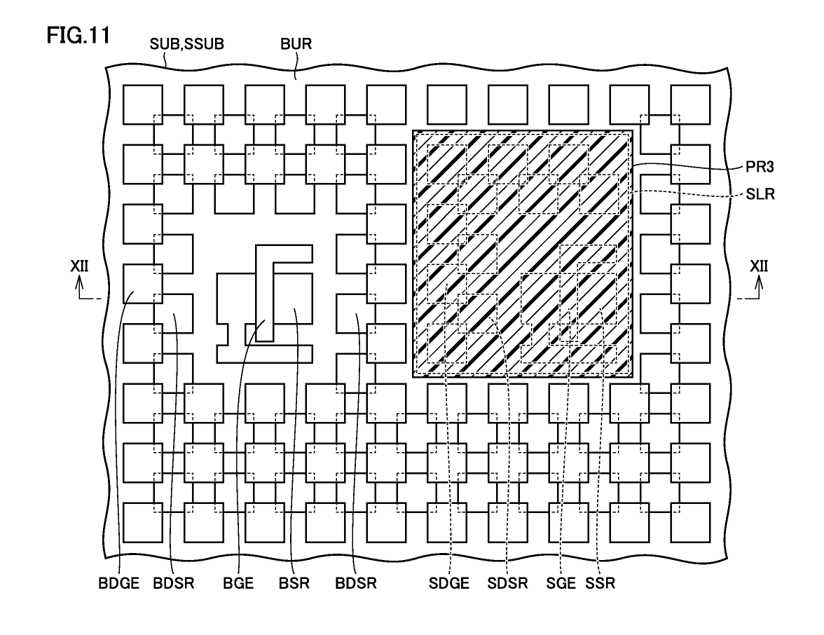

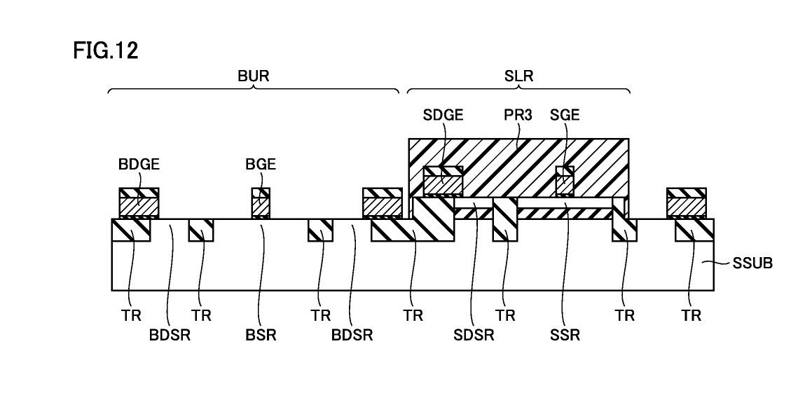

As shown in FIGS. 11 and 12, a photoresist PR3 covering the entire SOI region is formed through prescribed photolithography. A technique for creating a pattern of photoresist PR3 will be described in the last embodiment. Photoresist PR3 is formed to cover not only SOI region SLR but also a region where a p-channel type bulk transistor (not shown) is to be formed.

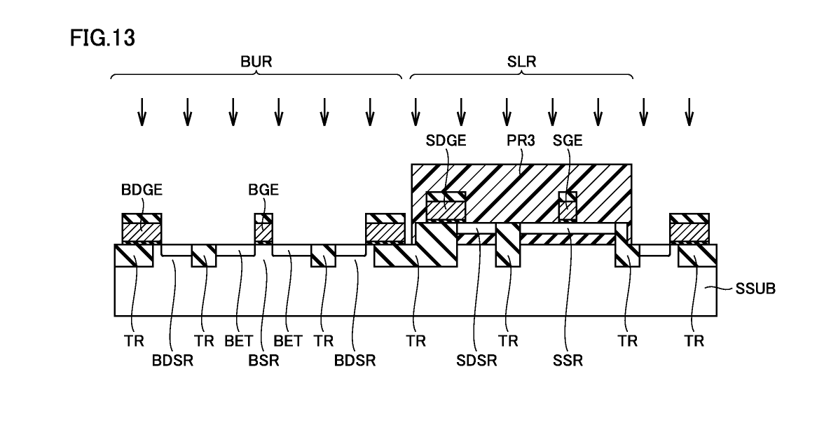

Then, as shown in FIG. 13, an extension region BET is formed in element formation region BSR by implanting an impurity into an n-type region with photoresist PR3 serving as an implantation mask. An impurity into the n-type region is exemplified by nitrogen (N₂), arsenic (As), and phosphorus (P). In particular, in a case of nitrogen (N₂), a concentration of doping therewith is set approximately to 1×10²⁰ cm⁻³. Here, the n-type impurity is implanted also into dummy element formation region BDSR in bulk region BUR. Thereafter, photoresist PR3 is removed.

Then, extension implantation of a p-channel type bulk transistor (not shown) is carried out. An extension region (not shown) is formed, for example, by implanting boron fluoride (BF₂) with a photoresist (not shown) covering the SOI region and a region where an n-channel type bulk transistor is to be formed serving as an implantation mask.

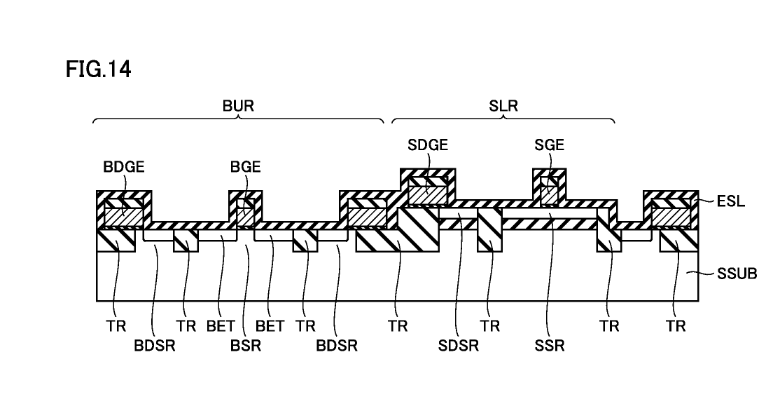

Then, in forming an elevated epitaxial layer in a prescribed region in SOI region SLR, a film preventing formation of an epitaxial layer in a region other than the prescribed region (a protection film) is formed. As shown in FIG. 14, for example, a silicon nitride film ESL is formed to cover gate electrodes SGE and BGE and dummy gate electrodes SDGE and BDGE.

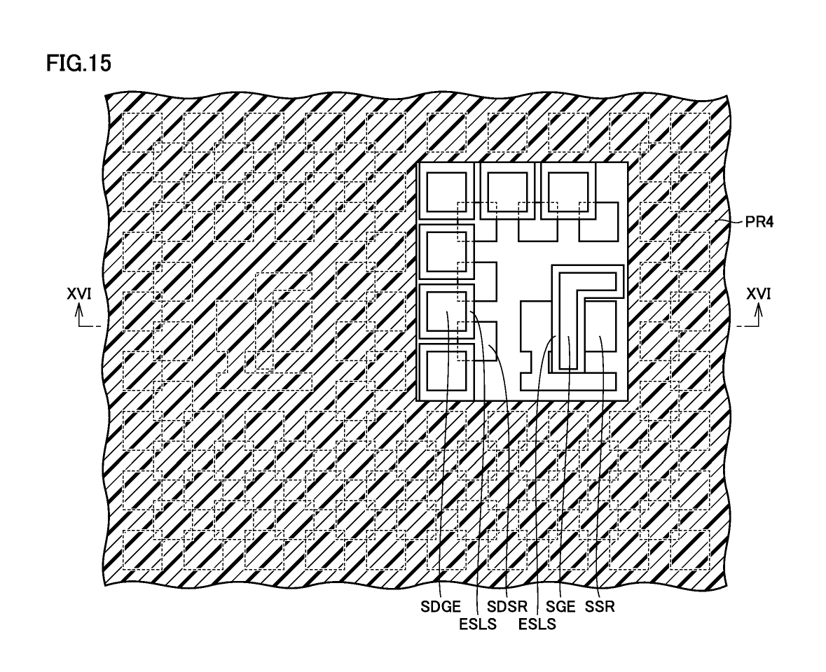

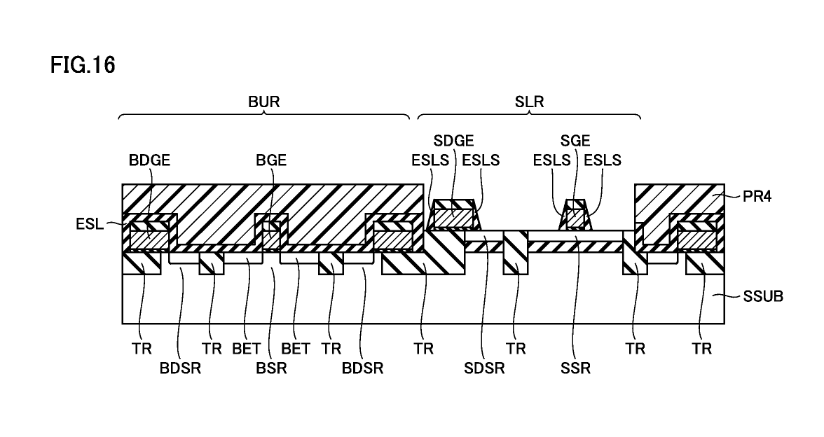

Then, as shown in FIGS. 15 and 16, a photoresist PR4 exposing SOI region SLR and covering bulk region BUR is formed through prescribed photolithography. Then, a portion of silicon layer SL located in element formation region SSR where an elevated epitaxial layer is to be formed is exposed through anisotropic etching treatment onto exposed silicon nitride film ESL with photoresist PR4 serving as an etching mask.

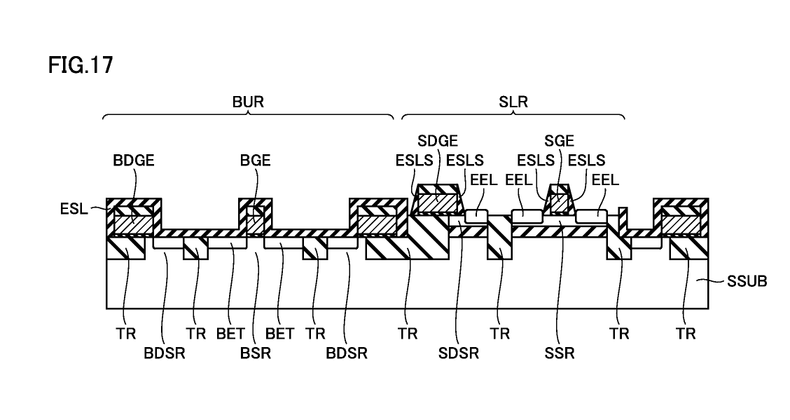

Here, silicon nitride film ESL remains as a sidewall protection film ESLS on a sidewall of gate electrode SGE. Thereafter, photoresist PR4 is removed. Then, as shown in FIG. 17, an elevated epitaxial layer EEL is formed in exposed element formation region SSR with an epitaxial growth method.

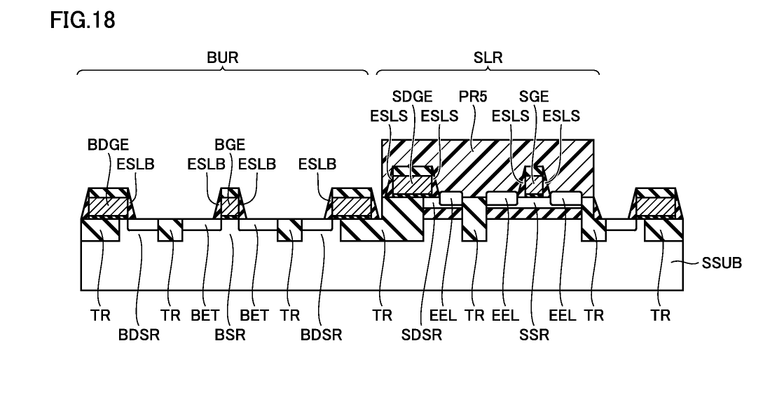

Then, as shown in FIG. 18, a photoresist PR5 covering SOI region SLR and exposing bulk region BUR is formed through prescribed photolithography. Then, a surface of silicon substrate SSUB located in element formation region BSR is exposed through anisotropic etching of exposed silicon nitride film ESL with photoresist PR5 serving as an etching mask. In addition, a sidewall protection film ESLB is formed on a sidewall of gate electrode BGE. Thereafter, photoresist PR5 is removed.

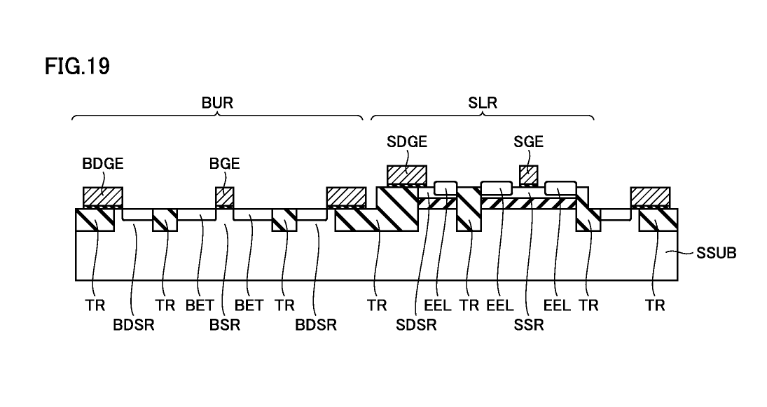

Then, as shown in FIG. 19, sidewall protection films ESLS and ESLB are removed through prescribed wet etching treatment. Here, similarly to a state of SOI region SLR where sidewall protection film ESLS remains on the sidewall of gate electrode SGE, in bulk region BUR, sidewall protection film ESLB remains on the sidewall of gate electrode BGE. Thus, as compared with a case that the entire bulk region BUR is covered with silicon nitride film ESL, damage caused by excessive etching of SOI region SLR can be suppressed.

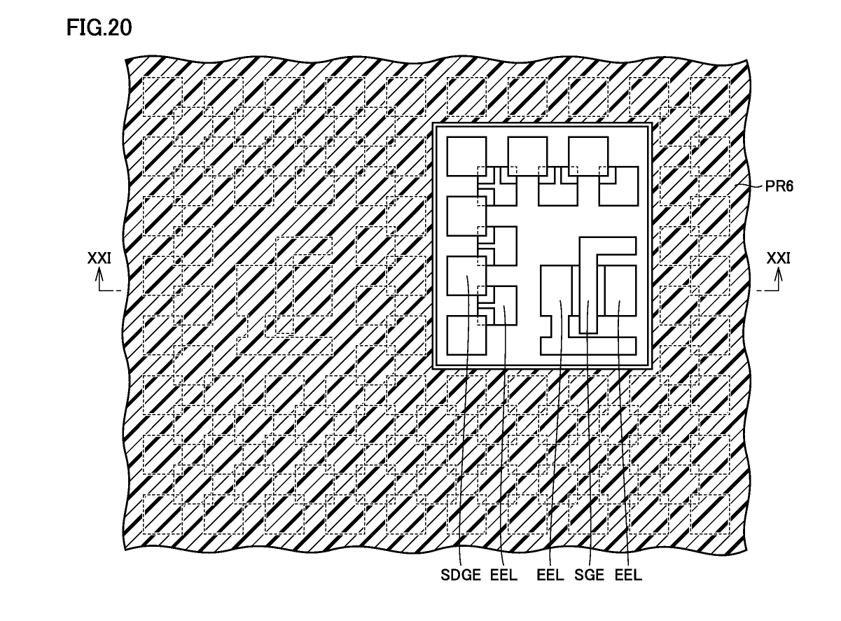

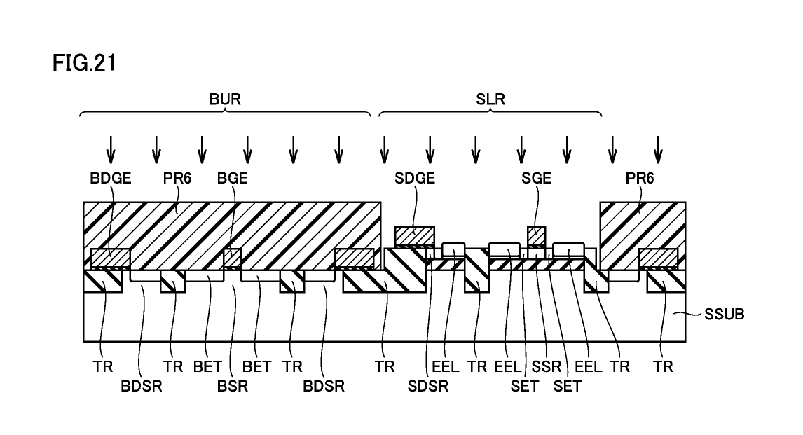

Then, extension implantation of the SOI transistor is carried out. Here, description will be given, assuming an n-channel type SOI transistor as an SOI transistor shown in the drawings. As shown in FIGS. 20 and 21, a photoresist PR6 exposing SOI region SLR and covering bulk region BUR is formed through prescribed photolithography.

Then, an extension region SET is formed in element formation region SSR by implanting, for example, an n-type impurity such as arsenic (As) with photoresist PR6 serving as an implantation mask. Here, the n-type impurity is implanted also in a dummy element formation region SDSR in SOI region SLR. Thereafter, photoresist PR6 is removed.

Then, extension implantation of a p-channel type SOI transistor (not shown) is carried out. An extension region (not shown) is formed, for example, by implanting boron fluoride (BF₂) with a photoresist (not shown) covering the bulk region and a region where an n-channel type SOI transistor is to be formed serving as an implantation mask.

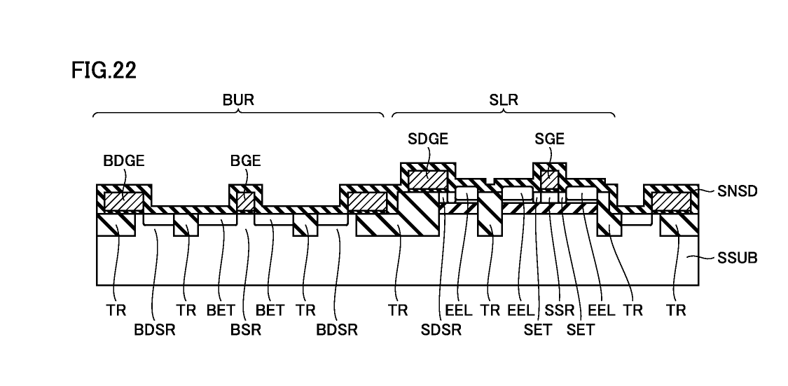

Then, a sidewall film is formed on the sidewall of each of gate electrodes SGE and BGE. As shown in FIG. 22, a silicon nitride film SNSD is formed to cover gate electrodes SGE and BGE and dummy gate electrodes SDGE and BDGE.

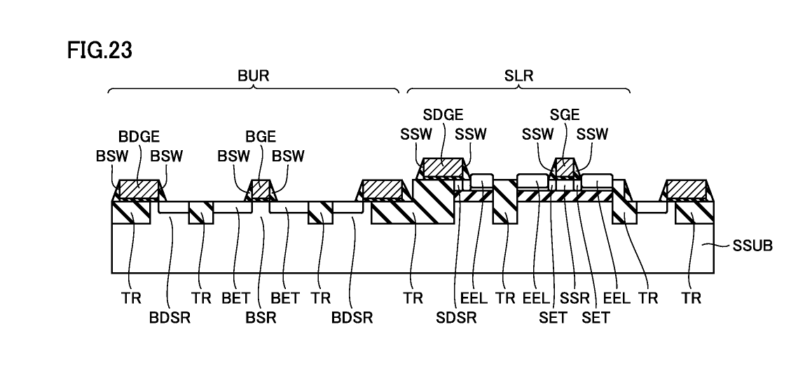

Then, as shown in FIG. 23, by anisotropically etching the entire surface of silicon nitride film SNSD, a sidewall film SSW is formed on the sidewall of each of gate electrode SGE and dummy gate electrode SDGE in SOI region SLR. In bulk region BUR, a sidewall film BSW is formed on a sidewall of each of gate electrode BGE and dummy gate electrode BDGE.

Then, source-drain implantation of each of the SOI transistor and the bulk transistor of the n-channel type is carried out. A photoresist (not shown) covering a region where the SOI transistor and the bulk transistor of the p-channel type are each formed and exposing a region where the SOI transistor and the bulk transistor of the n-channel type are formed is formed.

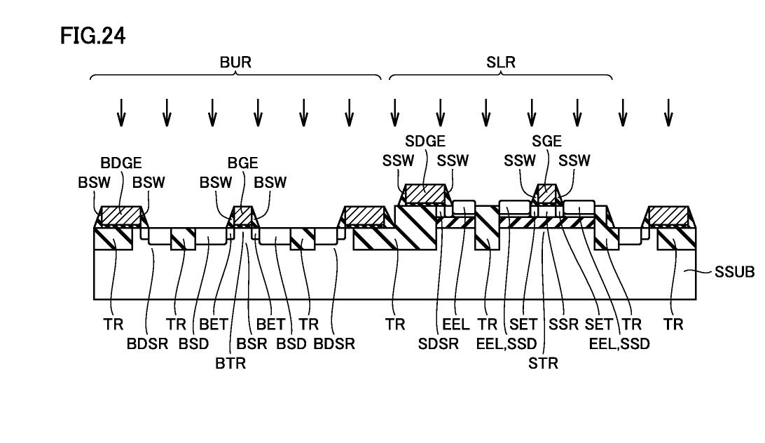

Then, as shown in FIG. 24, by implanting, for example, arsenic (As) and phosphorus (P) as an n-type impurity into the exposed region, a source-drain region SSD is formed in SOI region SLR. In bulk region BUR, a source-drain region BSD is formed. Thus, an SOI transistor STR is formed in SOI region SLR, and a bulk transistor BTR is formed in bulk region BUR.

Then, source-drain implantation of each of an SOI transistor and a bulk transistor of the p-channel type is carried out. A source-drain region (not shown) is formed, for example, by implanting boron (B) as a p-type impurity, with a photoresist (not shown) exposing a region where an SOI transistor and a bulk transistor of the p-channel type are to be formed and covering a region where an SOI transistor and a bulk transistor of the n-channel type are to be formed serving as an implantation mask.

Then, a metal silicide film is formed with a Self ALIgned siliCIDE (SALICIDE) method. For example, a metal film (not shown) such as a cobalt film is formed to cover gate electrodes SGE and BGE, dummy gate electrodes SDGE and BDGE, and source-drain regions SSD and BSD. Then, heat treatment at a prescribed temperature is performed.

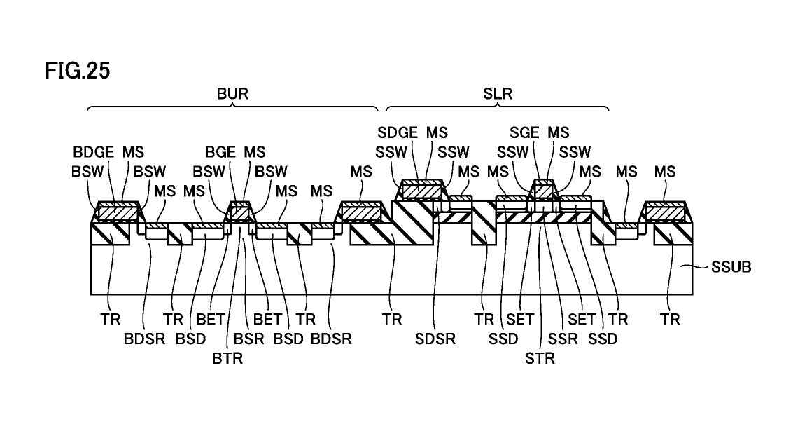

Thus, a metal silicide film is formed as a result of reaction between a metal and a silicon in gate electrodes SGE and BGE and dummy gate electrodes SDGE and BDGE. In addition, a metal silicide film is formed as a result of reaction between a metal and silicon in source-drain regions SSD and BSD. Thereafter, by removing an unreacted metal film, a metal silicide film MS is exposed as shown in FIG. 25.

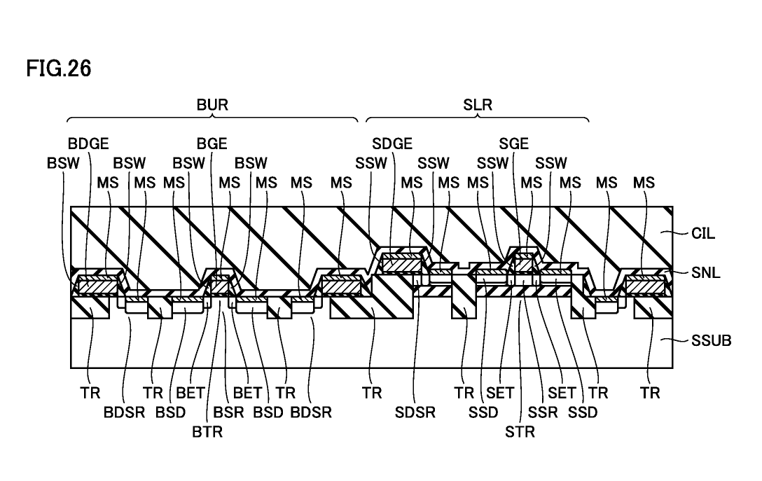

Then, as shown in FIG. 26, a silicon nitride film SNL is formed as a stress liner film so as to cover the SOI transistor and the bulk transistor. Then, a contact interlayer insulating film CIL such as a silicon oxide film having a prescribed thickness is formed to cover silicon nitride film SNL.

Then, a contact hole exposing metal silicide film MS is formed through prescribed photolithography and etching treatment onto contact interlayer insulating film CIL. Then, a tungsten (W) film is formed, for example, with a titanium (Ti) film (neither of which is shown) being interposed, which serves as a barrier metal, on a surface of contact interlayer insulating film CIL including a sidewall surface of the contact hole. Then, a portion of the tungsten film and a portion of the titanium film located on an upper surface of contact interlayer insulating film CIL are removed through chemical mechanical polishing treatment.

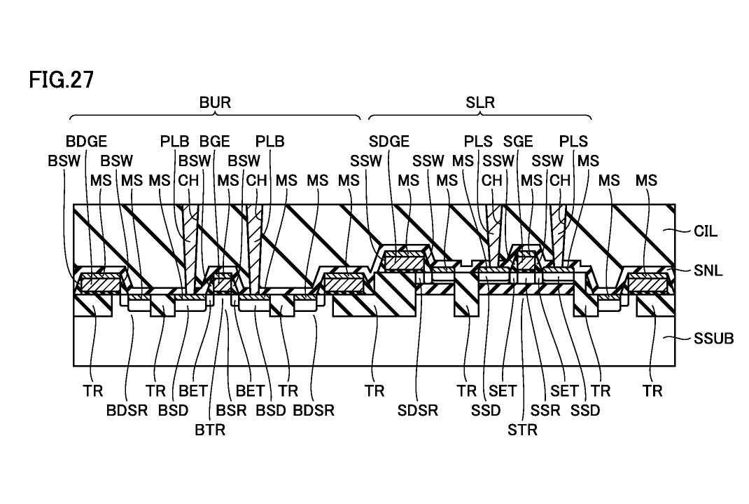

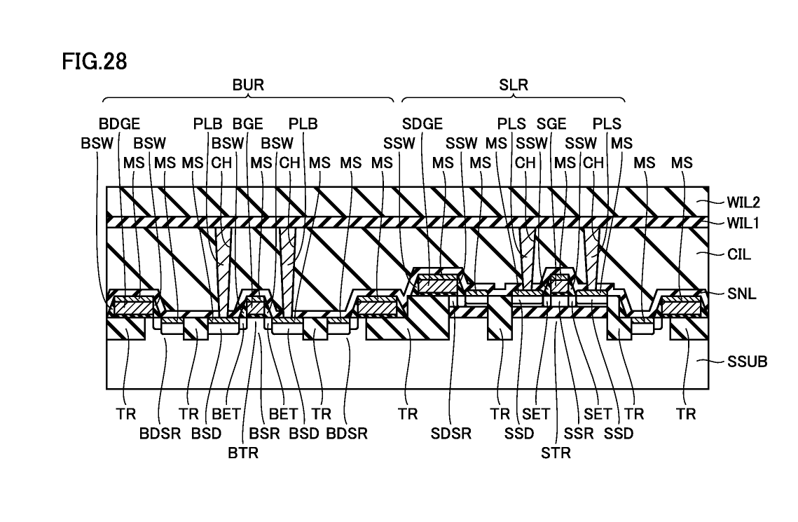

Thus, as shown in FIG. 27, a contact plug PLS is formed within a contact hole CH in SOI region SLR. A contact plug PLB is formed within contact hole CH in bulk region BUR. Then, as shown in FIG. 28, an interconnection interlayer insulating film WIL1 is formed to cover contact interlayer insulating film CIL. Furthermore, an interconnection interlayer insulating film WIL2 is formed to cover interconnection interlayer insulating film WILL

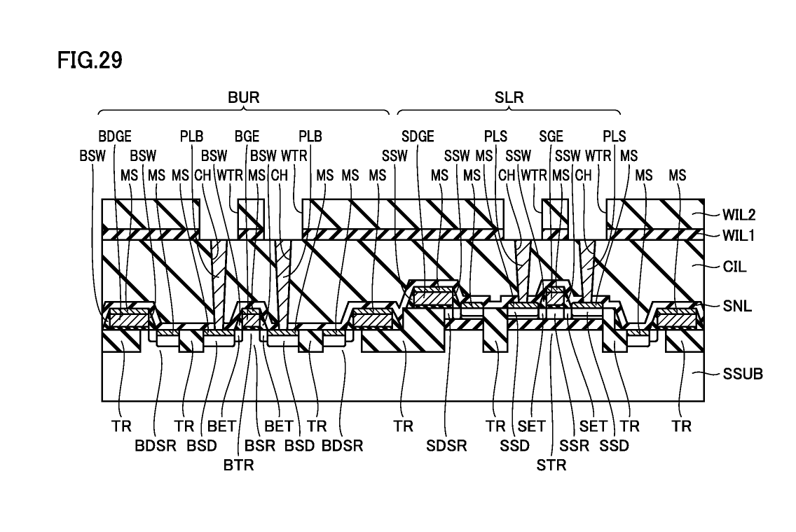

Then, as shown in FIG. 29, an interconnection groove WTR exposing contact plug PLS is formed in SOI region SLR through prescribed photolithography and etching treatment onto interconnection interlayer insulating film WIL2 and interconnection interlayer insulating film WILL Interconnection groove WTR exposing contact plug PLB is formed in bulk region BUR.

Then, a copper (Cu) film is formed, for example, with a tantalum (Ta) film (neither of which is shown) being interposed, which serves as a barrier metal, on a surface of interconnection interlayer insulating film WIL2 including a bottom surface and a sidewall surface of interconnection groove WTR. Then, a portion of the copper film and a portion of the tantalum film located on an upper surface of interconnection interlayer insulating film WIL2 are removed through chemical mechanical polishing treatment.

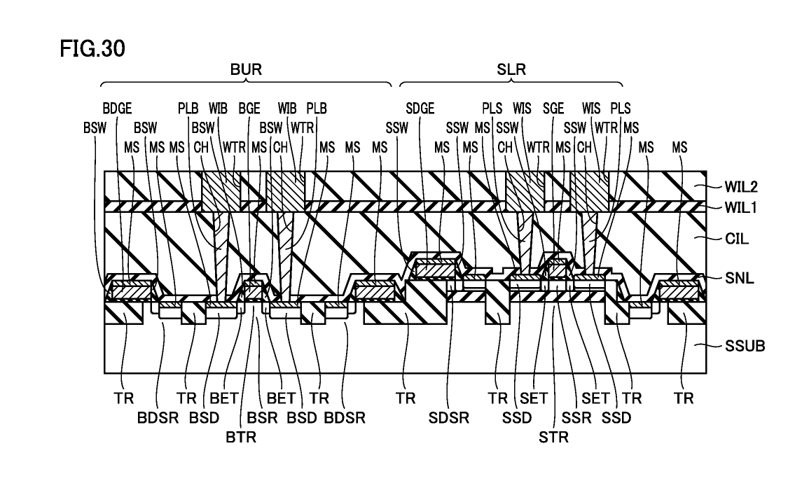

Thus, as shown in FIG. 30, an interconnection WIS is formed in interconnection groove WTR in SOI region SLR. An interconnection WIB is formed in interconnection groove WTR in bulk region BUR. Interconnection WIS is electrically connected to source-drain region SSD of the SOI transistor through contact plug PLS and metal silicide film MS. Interconnection WIB is electrically connected to source-drain region BSD of the bulk transistor through contact plug PLB and metal silicide film MS.

Thereafter, as necessary, an upper interlayer insulating film and an interconnection (neither of which is shown) are formed. Thus, a main portion of a semiconductor device including an SOI transistor and a bulk transistor is completed. In the semiconductor device described above, abnormal growth of an epitaxial layer in SOI region SLR can be suppressed in formation of elevated epitaxial layer EEL by exposing isolation region TR (trench isolation insulating film TL) along the entire perimeter on the sidewall of the step between SOI region SLR and bulk region BUR. In addition, abnormal growth of the epitaxial growth layer in SOI region SLR can be suppressed by forming photoresist PR3 covering SOI region SLR in extension implantation into bulk region BUR, which will be described in comparison with a semiconductor device according to a comparative example.

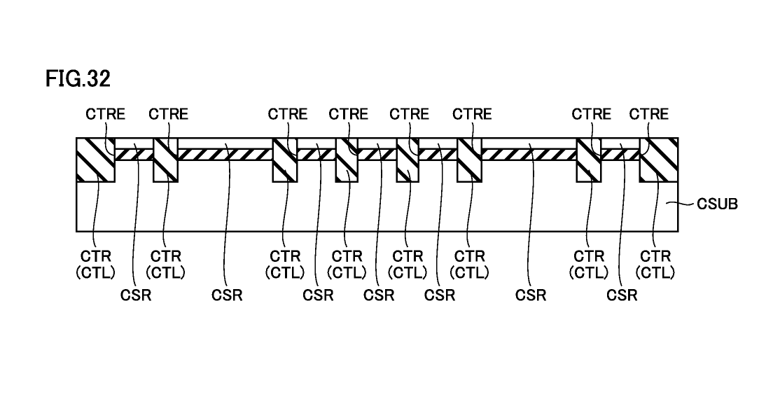

A trench isolation groove CTRE (see FIG. 32) for forming an isolation region is formed through prescribed photolithography and etching treatment onto a prepared SOI substrate CSUB. Then, an insulating film (not shown) such as a silicon oxide film is formed on SOI substrate CSUB so as to bury that trench isolation groove CTRE.

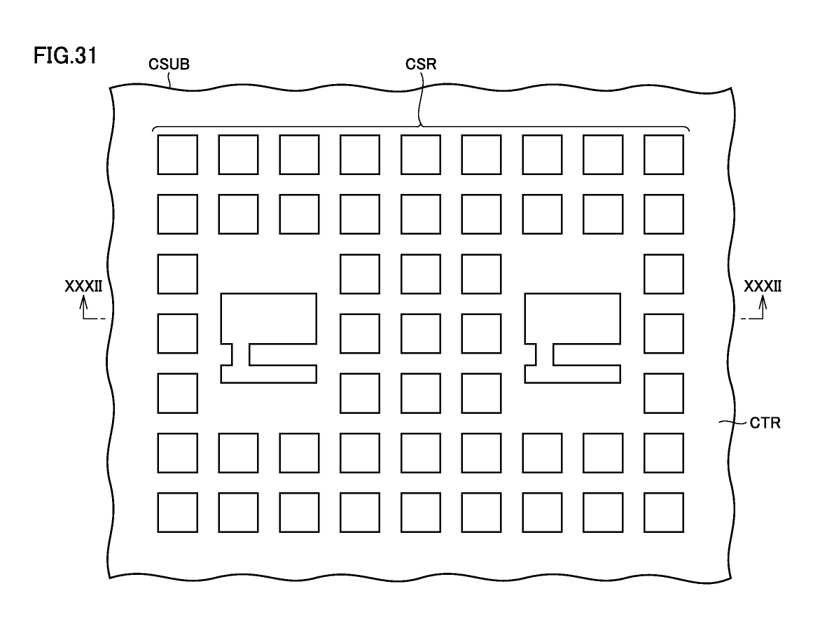

Then, as shown in FIGS. 31 and 32, an isolation region CTR is formed by a trench isolation insulating film CTL which remains within trench isolation groove CTRE, by performing chemical mechanical polishing treatment for removing a portion of the insulating film located on an upper surface of SOI substrate CSUB. Isolation region CTR defines an element formation region CSR.

In element formation region CSR (isolation region CTR) of the semiconductor device according to the comparative example, a boundary between the SOI region and the bulk region is not taken into consideration, and such a pattern that element formation region CSR is located across the boundary is present as a pattern of element formation region CSR.

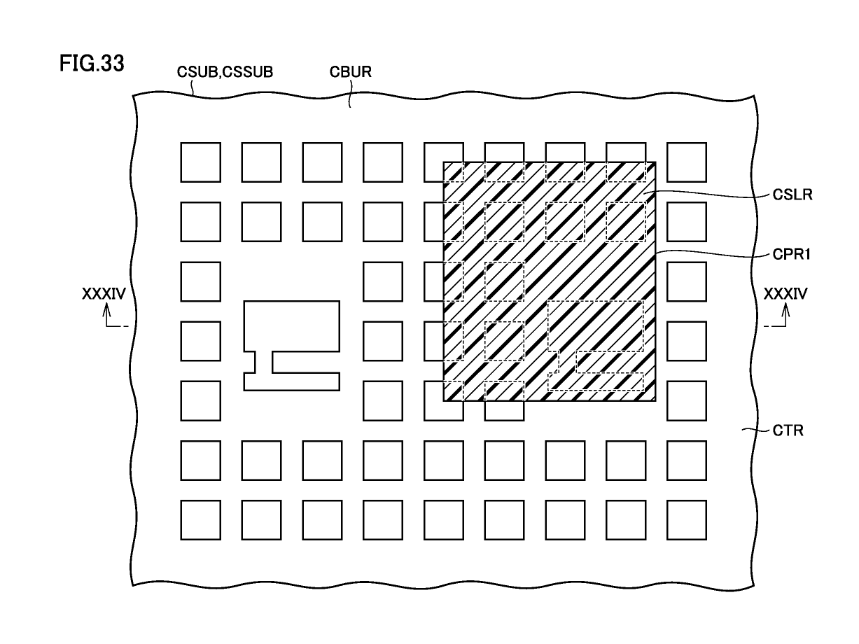

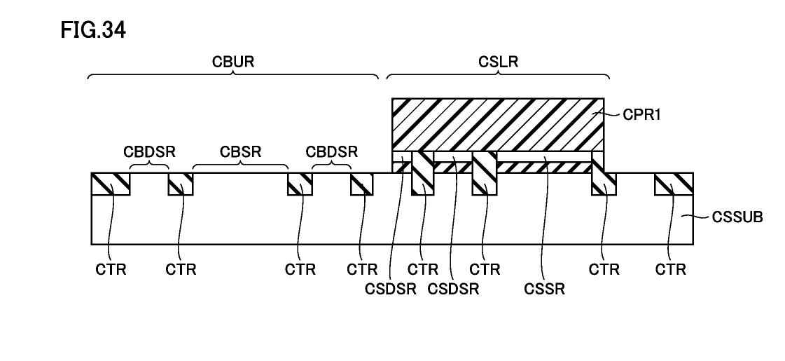

Then, as shown in FIGS. 33 and 34, a photoresist CPR1 is formed on a region where an SOI region is to be arranged through prescribed photolithography. Then, a bulk region CBUR in which a surface of a silicon substrate CSSUB is exposed is formed through etching treatment onto an exposed region of SOI substrate CSUB with photoresist CPR1 serving as an etching mask.

In bulk region CBUR, a remaining isolation region CTR defines an element formation region CBSR and a dummy element formation region CBDSR. On the other hand, a portion of SOI substrate CSUB which remains without being etched serves as an SOI region CSLR. In SOI region CSLR, isolation region CTR defines an element formation region CSSR and a dummy element formation region CSDSR. Thereafter, photoresist CPR1 is removed.

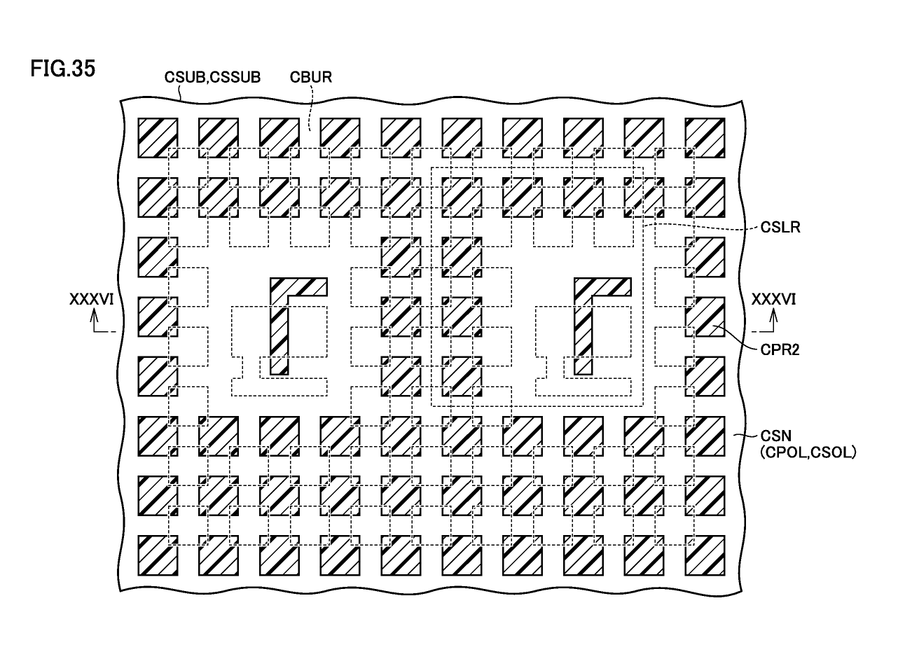

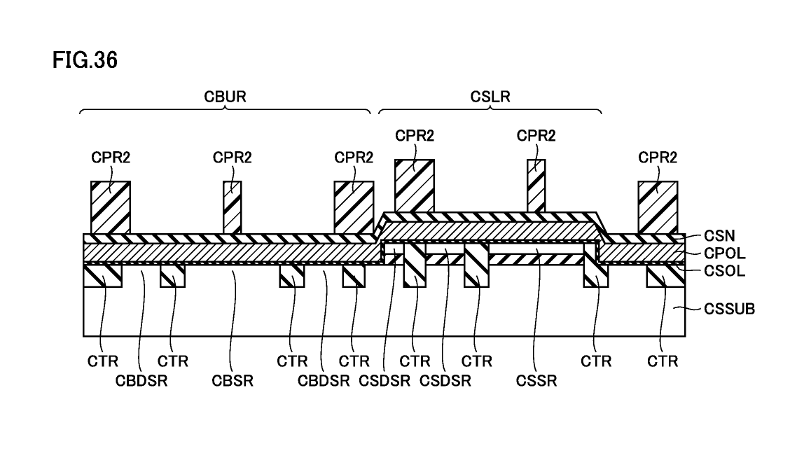

Then, a gate electrode (a gate interconnection) is formed. As shown in FIGS. 35 and 36, a silicon oxide film CSOL serving as a gate oxide film is formed. A polysilicon film CPOL is formed to cover silicon oxide film CSOL. A silicon nitride film CSN is formed to cover polysilicon film CPOL. A photoresist CPR 2 for patterning a gate electrode is formed through prescribed photolithography. Such a pattern that a gate electrode is located across a boundary is present as a pattern of the gate electrode (gate interconnection) of the semiconductor device according to the comparative example.

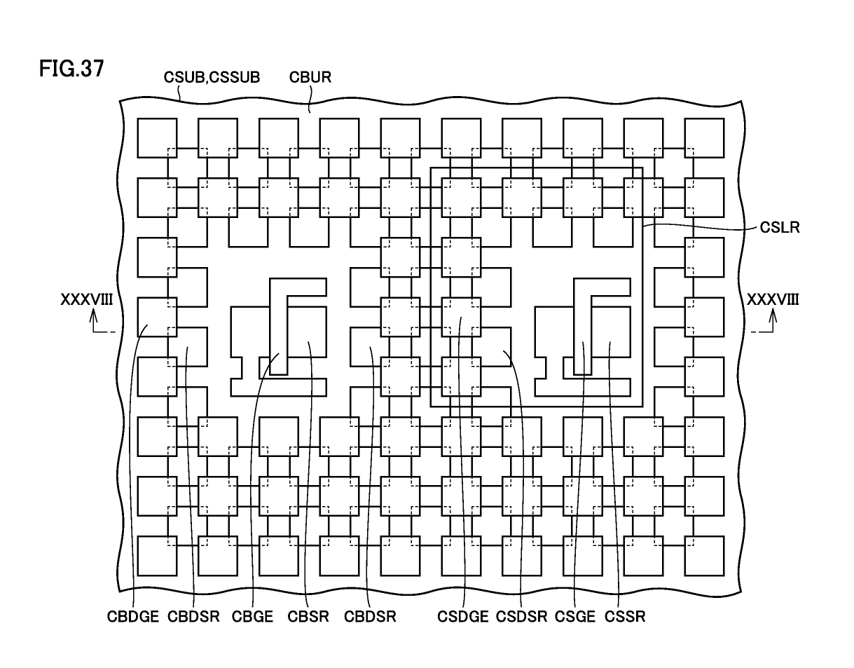

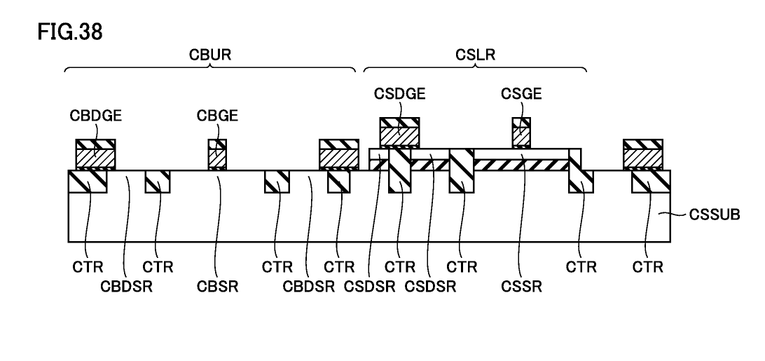

Then, a gate electrode is formed through etching treatment with photoresist CPR2 serving as an etching mask. Thereafter, photoresist CPR2 is removed. Thus, as shown in FIGS. 37 and 38, a gate electrode CSGE and a dummy gate electrode CSDGE are formed in SOI region CSLR. A gate electrode CBGE and a dummy gate electrode CBDGE are formed in bulk region CBUR. A dummy gate electrode lying across the boundary between SOI region CSLR and bulk region CBUR is present at the dummy gate electrode.

Then, extension implantation of the bulk transistor is carried out. Here, description will be given, assuming an n-channel type bulk transistor as a bulk transistor shown in the drawings.

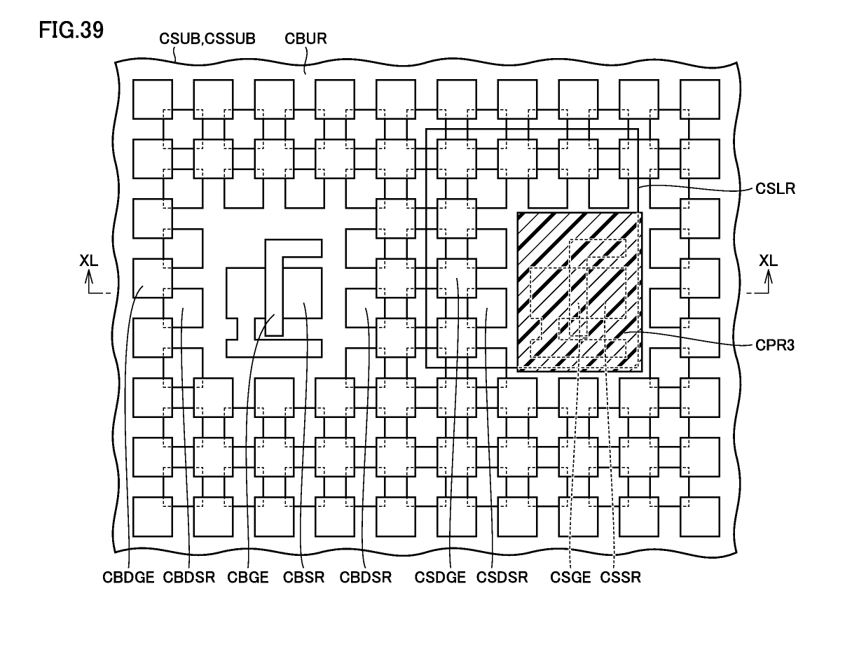

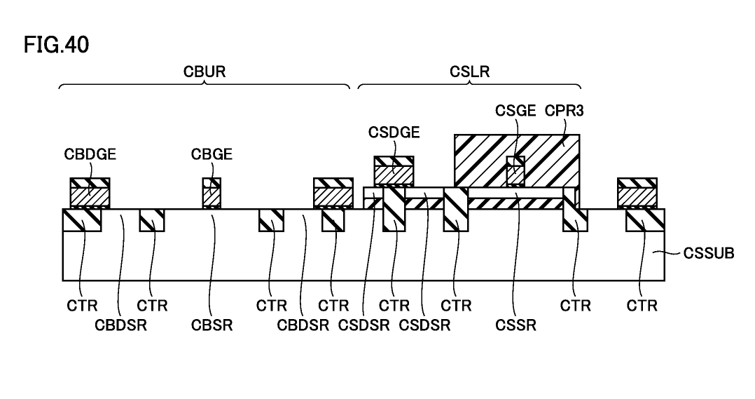

As shown in FIGS. 39 and 40, a photoresist CPR3 covering an element formation region CSSR in SOI region CSLR is formed through prescribed photolithography. Photoresist CPR 3 covers also a region where a p-channel type bulk transistor (not shown) is to be formed.

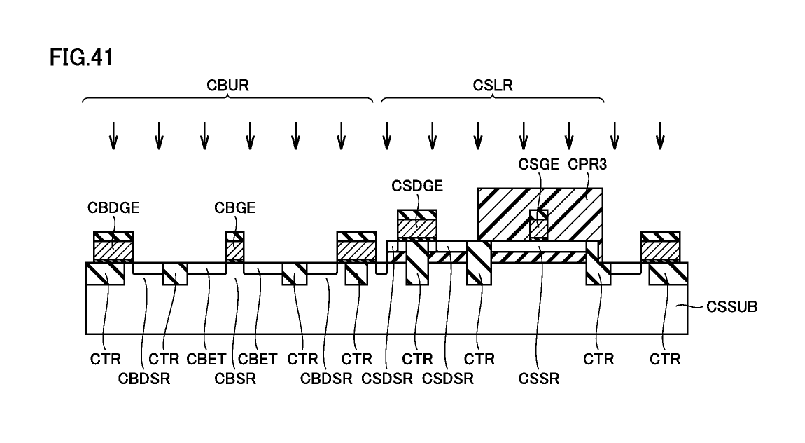

Then, as shown in FIG. 41, an extension region CBET is formed in element formation region CBSR by implanting an impurity into an n-type region with photoresist CPR3 serving as an implantation mask. Here, the impurity into the n-type region will be implanted also into dummy element formation region CBDSR in bulk region CBUR. Thereafter, photoresist CPR3 is removed.

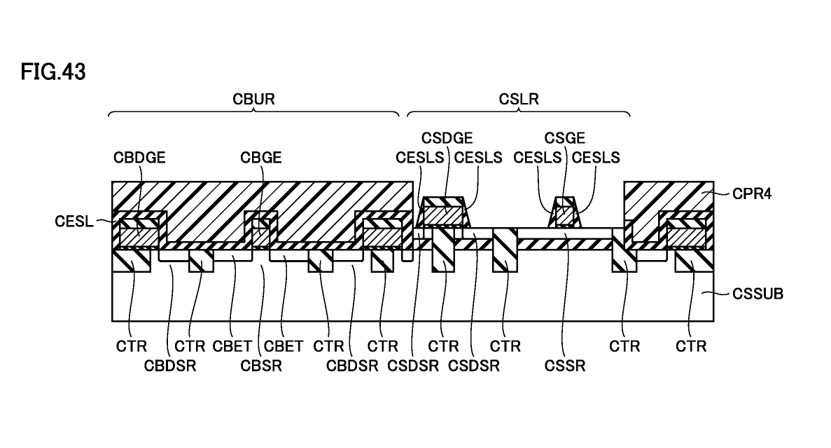

Then, after extension implantation of a p-channel type bulk transistor (not shown) is carried out, a film preventing an epitaxial layer from being formed in a region other than a prescribed region is formed. A silicon nitride film CESL (see FIG. 43) is formed to cover gate electrodes CSGE and CBGE and dummy gate electrodes CSDGE and CBDGE.

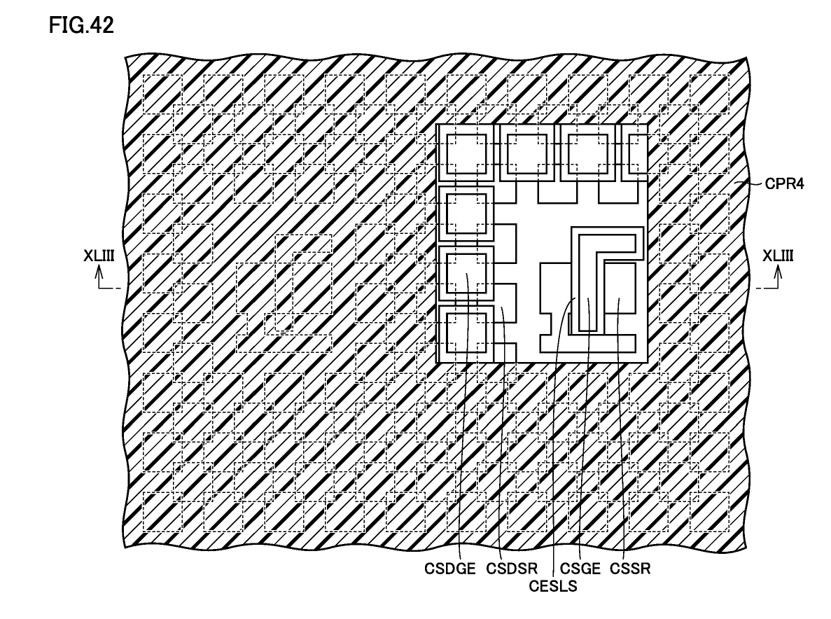

Then, as shown in FIGS. 42 and 43, a photoresist CPR4 exposing SOI region CSLR and covering bulk region CBUR is formed through prescribed photolithography. Then, a portion of a silicon layer CSL located in element formation region CSSR where an elevated epitaxial layer is to be formed is exposed through anisotropic etching treatment onto exposed silicon nitride film CESL with photoresist CPR4 serving as an etching mask. In addition, silicon nitride film CESL remains as a sidewall protection film CESLS on a sidewall of gate electrode CSGE. Thereafter, photoresist CPR4 is removed.

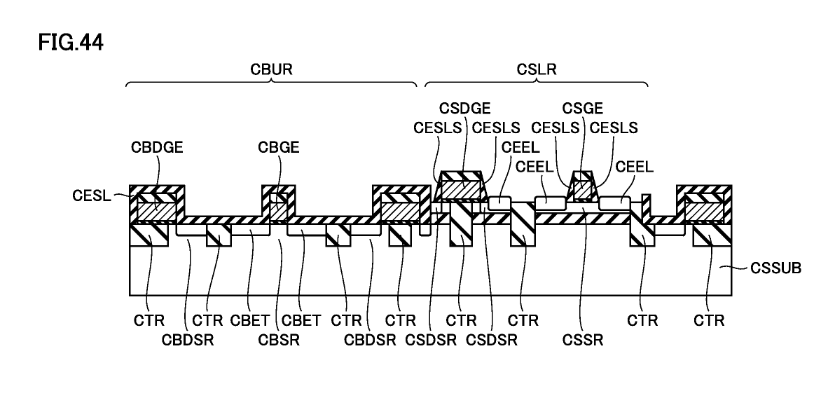

Then, as shown in FIG. 44, an elevated epitaxial layer CEEL is formed in exposed element formation region CSSR through an epitaxial growth method. Thereafter, an extension region of the SOI transistor, a source-drain region of each of the SOI transistor and the bulk transistor, a contact plug, and an interconnection (none of which is shown) are formed, and a main portion of the semiconductor device according to the comparative example is completed.

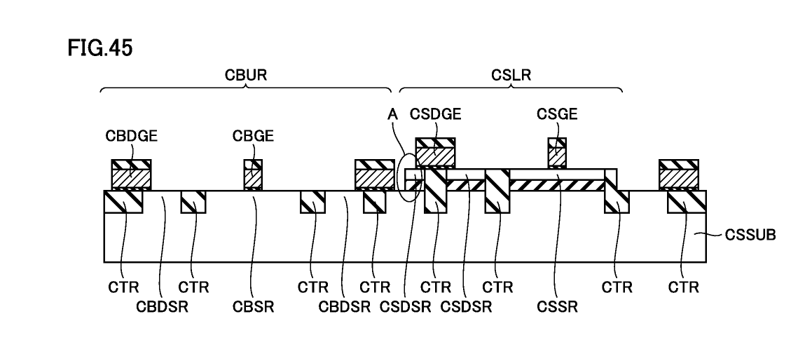

In the semiconductor device according to the comparative example, as shown with a circle A in FIG. 45, a pattern arranged such that a silicon layer is exposed at the boundary between SOI region CSLR and bulk region CBUR is present as a pattern of dummy element formation region CSDSR. Therefore, in formation of the elevated epitaxial layer, an epitaxial layer may abnormally grow on a portion of the silicon layer exposed at a step at the boundary between the SOI region and the bulk region.

As shown in FIG. 41, in formation of an extension region of the bulk transistor, an impurity is implanted into a portion of the silicon layer exposed at SOI region CSLR, and consequently the silicon layer may become amorphous. Therefore, in formation of the elevated epitaxial layer, the epitaxial layer may abnormally grow on the portion of the amorphous silicon layer.

In contrast to the semiconductor device according to the comparative example, in the semiconductor device according to the embodiment, isolation region TR (trench isolation insulating film TL) is exposed along the entire perimeter of the sidewall of the step between SOI region SLR and bulk region BUR. Thus, abnormal growth of an epitaxial layer in SOI region SLR can be suppressed in formation of elevated epitaxial layer EEL.

In extension implantation into bulk region BUR, photoresist PR3 covering SOI region SLR is formed. Thus, the silicon layer located in the SOI region can be prevented from becoming amorphous, and abnormal growth of the epitaxial layer in SOI region SLR can be suppressed.

Furthermore, elimination of the buried oxide film exposed at the sidewall of the step between SOI region SLR and bulk region BUR in a subsequent step and separation of a portion of the silicon layer located thereon as a foreign substance can be suppressed.

### Second Embodiment

Here, a technique for exposing an isolation insulating film of an isolation region along the entire perimeter of a sidewall of a step between an SOI region and a bulk region and covering the entire dummy element formation region arranged in the SOI region with a dummy electrode will be described. The same member as in the first embodiment has the same reference character allotted and description thereof will not be repeated unless it is necessary.

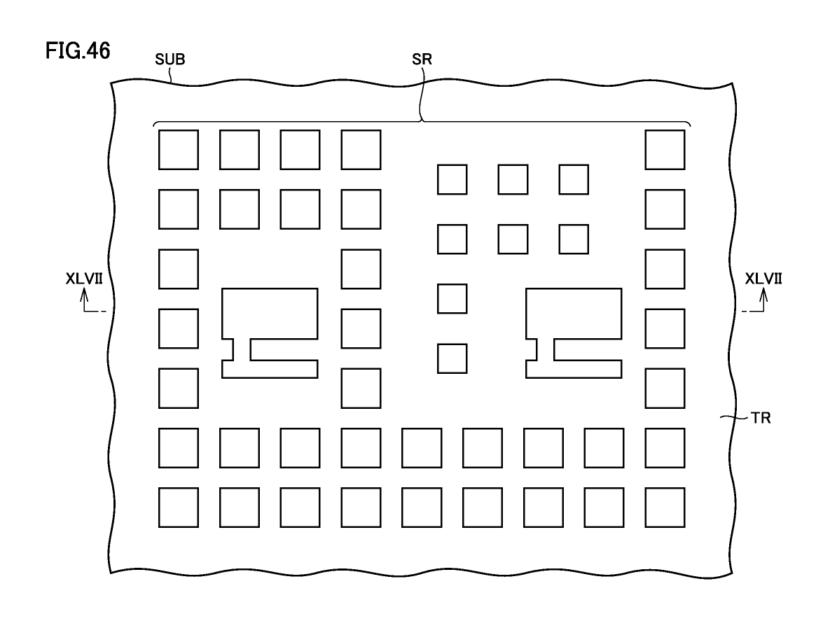

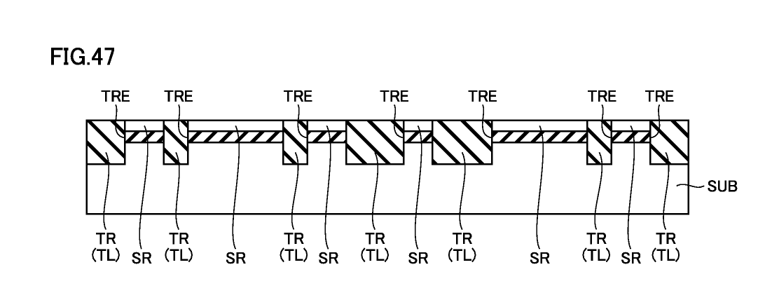

Initially, as shown in FIGS. 46 and 47, isolation region TR is formed in SOI substrate SUB through the process the same as the process shown in FIGS. 2 to 4. Isolation region TR defines element formation region SR. Element formation region SR includes an element formation region where a prescribed semiconductor element is to be formed and a dummy element formation region.

Then, the SOI region and the bulk region are formed through the process the same as the process shown in FIGS. 5 and 6. In bulk region BUR, remaining isolation region TR defines element formation region BSR where a bulk transistor is to be formed and dummy element formation region BDSR. In SOI region SLR, isolation region TR defines element formation region SSR where an SOI transistor is to be formed and dummy element formation region SDSR (see FIGS. 5 and 6).

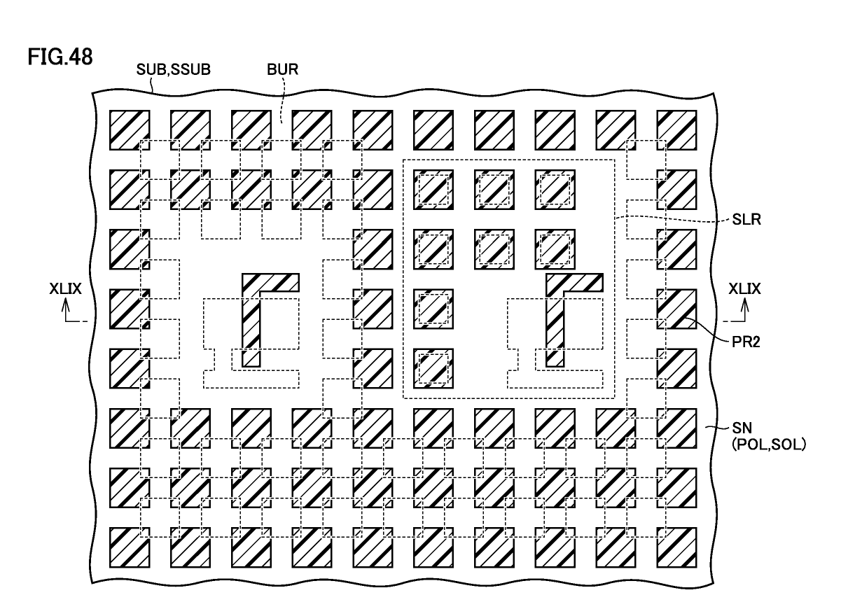

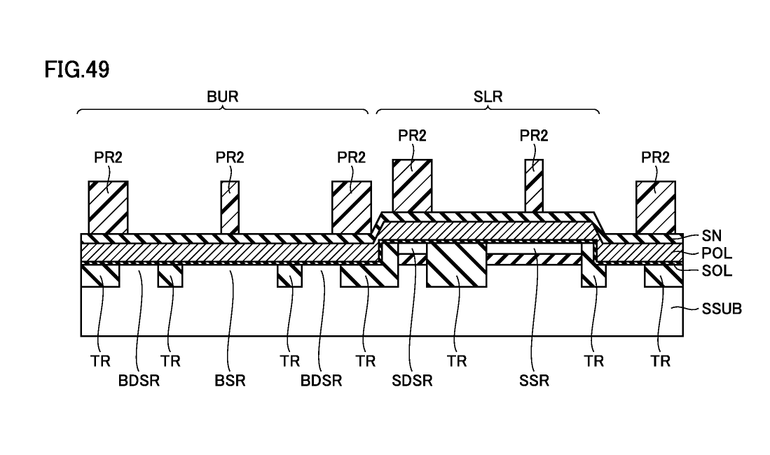

Then, a gate electrode (a gate interconnection) is formed. As shown in FIGS. 48 and 49, silicon oxide film SOL, polysilicon film POL, and silicon nitride film SN are successively formed through the process the same as the process shown in FIGS. 7 and 8. Then, photoresist PR2 for patterning a gate electrode is formed through prescribed photolithography. Here, photoresist PR2 is formed in SOI region SLR such that a patterned dummy gate electrode covers the entire single dummy element formation region SDSR. Namely, photoresist PR2 is formed such that the patterned dummy gate electrode (size) is larger than dummy element formation region SDSR (size).

Then, a hard mask for patterning a gate electrode is formed through etching treatment onto exposed silicon nitride film SN with photoresist PR2 serving as an etching mask. A gate electrode is formed through etching treatment with the hard mask serving as an etching mask. Thereafter, photoresist PR2 is removed.

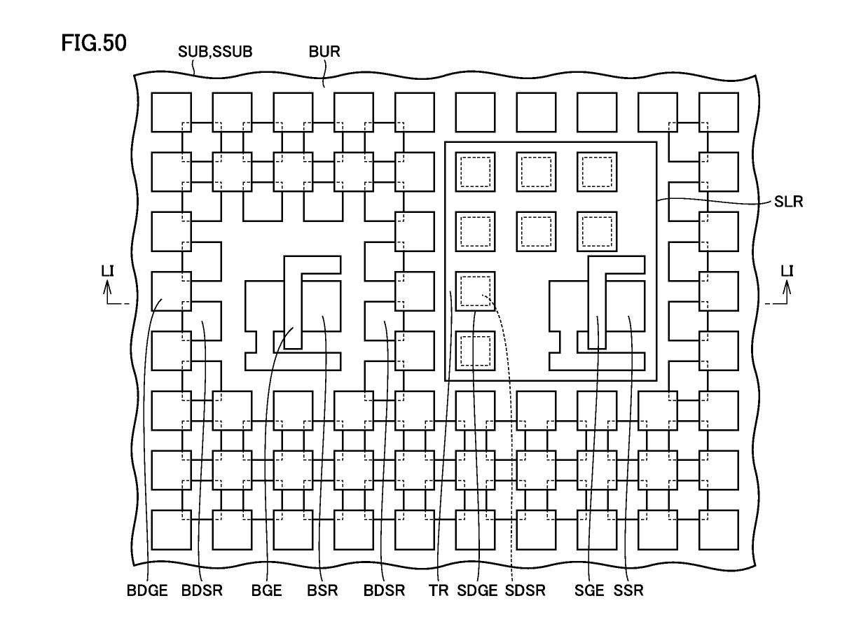

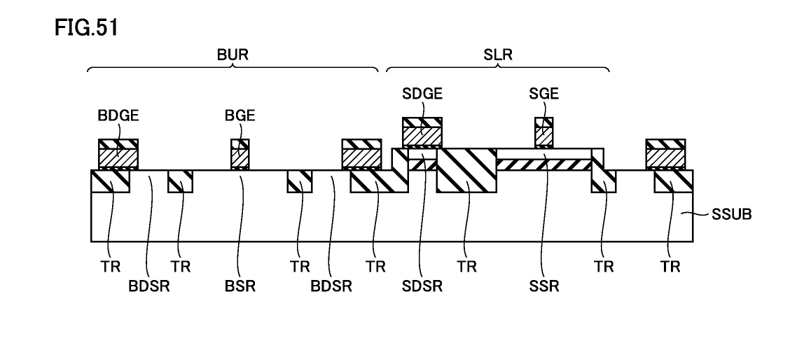

Thus, as shown in FIGS. 50 and 51, gate electrode SGE and dummy gate electrode SDGE are formed in SOI region SLR. Gate electrode SGE is arranged to extend across element formation region SSR. Dummy gate electrode SDGE is greater in size than dummy element formation region SDSR, and dummy gate electrode SDGE is arranged to cover the entire dummy element formation region SDSR. Gate electrode BGE and dummy gate electrode BDGE are formed in bulk region BUR. Gate electrode BGE is arranged to extend across element formation region BSR.

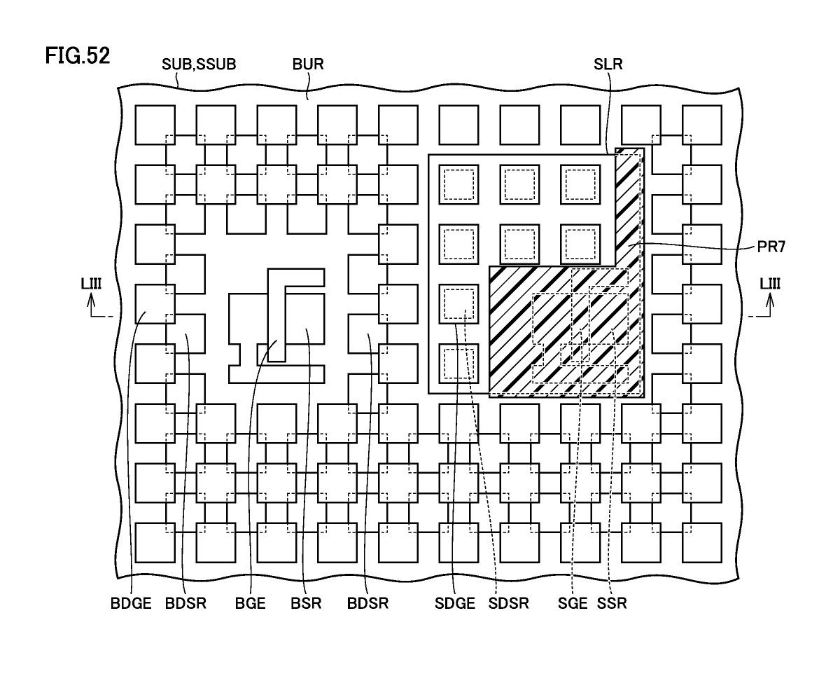

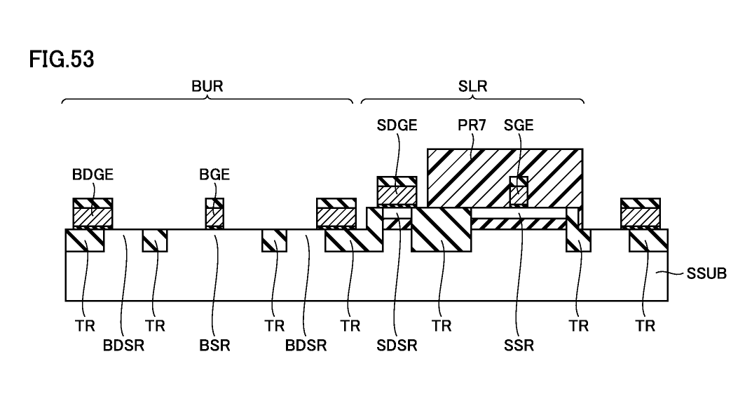

Then, extension implantation of the bulk transistor is carried out. Here, description will be given, assuming an n-channel type bulk transistor as a bulk transistor shown in the drawings. As shown in FIGS. 52 and 53, a photoresist PR7 is formed through prescribed photolithography.

Here, since dummy gate electrode SDGE is arranged to cover the entire dummy element formation region SDSR in SOI region SLR, the photoresist does not have to cover the entire SOI region SLR but photoresist PR7 covering element formation region SSR and a region in the vicinity thereof in SOI region SLR is formed. In addition, photoresist PR7 is formed to cover also a region where a p-channel type bulk transistor (not shown) is to be formed.

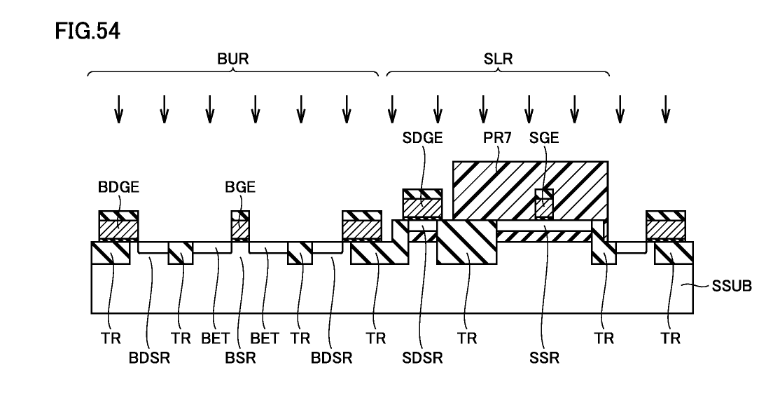

Then, as shown in FIG. 54, extension region BET is formed in element formation region BSR by implanting an n-type impurity with photoresist PR7 serving as an implantation mask. As described previously, an impurity of the n-type is exemplified by nitrogen (N₂), arsenic (As), and phosphorus (P). In particular, in a case of nitrogen (N₂), a concentration of doping therewith is set approximately to 1×10²⁰ cm⁻³. Thereafter, photoresist PR7 is removed. Then, extension implantation of a p-channel type bulk transistor (not shown) is carried out.

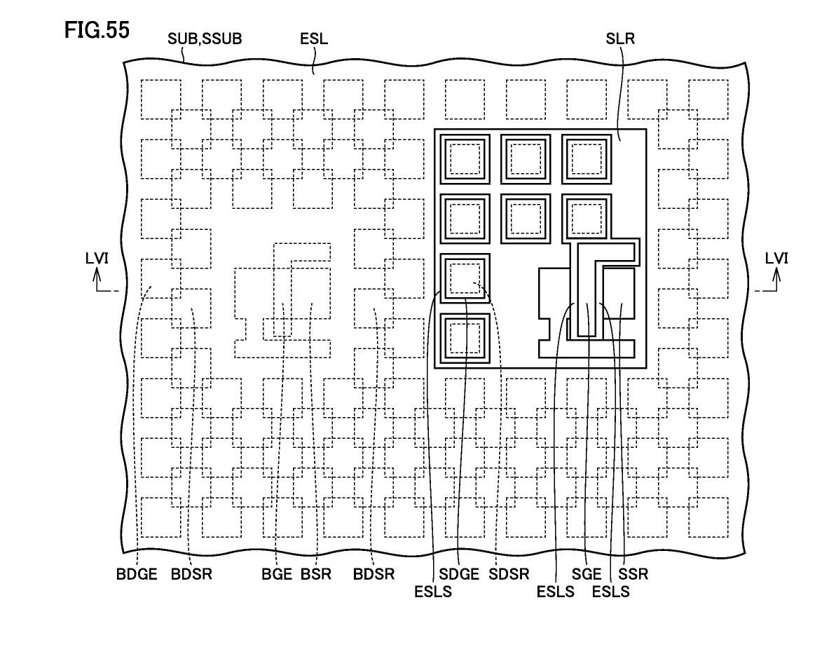

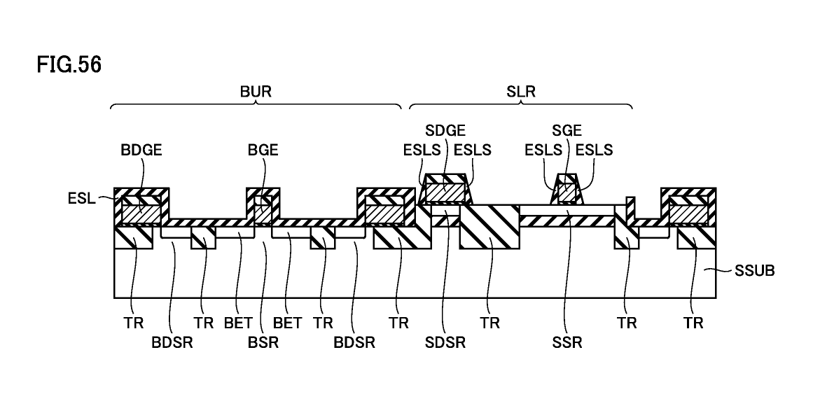

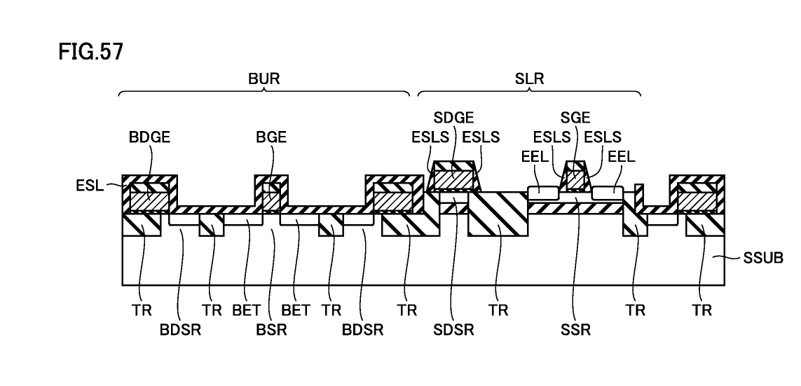

Then, a film preventing an epitaxial layer from being formed in a region other than a prescribed region is formed through the process the same as the process shown in FIGS. 14 to 16. As shown in FIGS. 55 and 56, silicon nitride film ESL exposing a portion of silicon layer SL located in element formation region SSR where an elevated epitaxial layer is to be formed and covering other regions is formed. Then, as shown in FIG. 57, elevated epitaxial layer EEL is formed in exposed element formation region SSR with the epitaxial growth method.

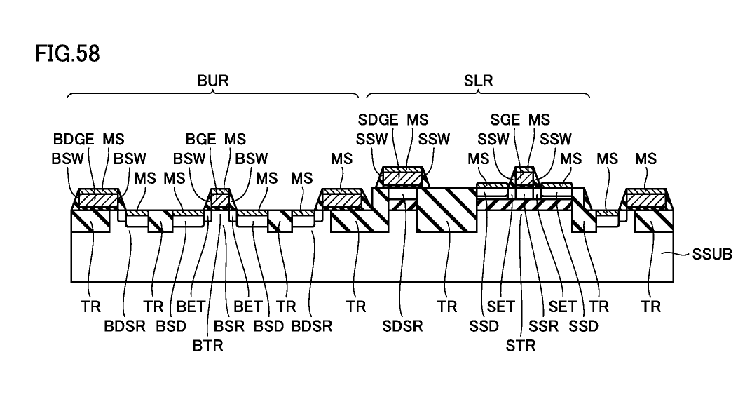

Then, silicon nitride film ESL is removed through the process the same as the process shown in FIGS. 18 and 19. Then, extension region SET is formed in element formation region SSR through the process the same as the process shown in FIGS. 20 and 21 (see FIG. 58). Then, through the process the same as the process shown in FIGS. 22 and 23, sidewall film SSW is formed on the sidewall of each of gate electrode SGE and dummy gate electrode SDGE in SOI region SLR, and sidewall film BSW is formed on the sidewall of each of gate electrode BGE and dummy gate electrode BDGE in bulk region BUR (see FIG. 58).

Then, through the process the same as the process shown in FIG. 24, source-drain region SSD is formed in SOI region SLR, and source-drain region BSD is formed in bulk region BUR (see FIG. 58). Thus, SOI transistor STR is formed in SOI region SLR, and bulk transistor BTR is formed in bulk region BUR. Then, as shown in FIG. 58, metal silicide film MS is formed through the process the same as the process shown in FIG. 25.

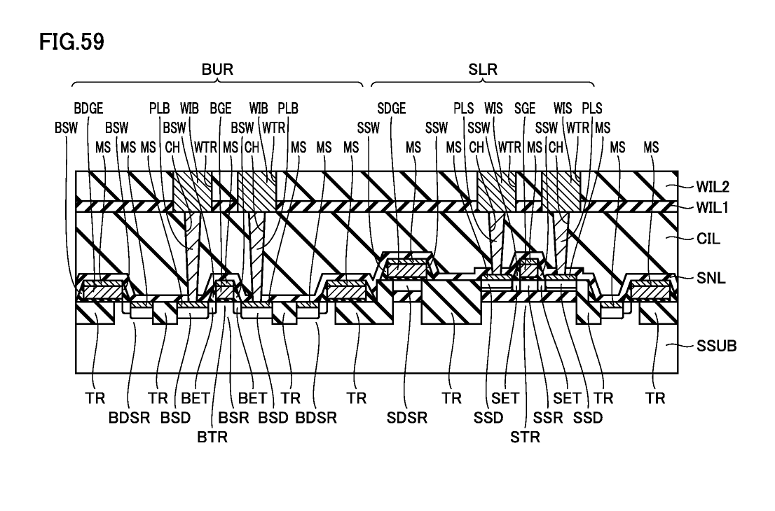

Then, silicon nitride film SNL and contact interlayer insulating film CIL are formed through the process the same as the process shown in FIG. 26 (see FIG. 59). Then, contact plugs PLS and PLB are formed in contact holes CH through the process the same as the process shown in FIG. 27 (see FIG. 59). Then, interconnection interlayer insulating film WIL1 and interconnection interlayer insulating film WIL2 are formed through the process the same as the process shown in FIG. 28 (see FIG. 59). Then, interconnection groove WTR is formed through the process the same as the process shown in FIG. 29 (see FIG. 59).

Then, as shown in FIG. 59, interconnection WIS is formed in SOI region SLR and interconnection WIB is formed in bulk region BUR through the process the same as the process shown in FIG. 30. Thereafter, as necessary, an upper interlayer insulating film and an interconnection (neither of which is shown) are formed. Thus, a main portion of a semiconductor device including an SOI transistor and a bulk transistor is completed.

In the semiconductor device described above, isolation region TR (trench isolation insulating film TL) is exposed along the entire perimeter of the sidewall of the step between SOI region SLR and bulk region BUR. Thus, abnormal growth of an epitaxial layer in SOI region SLR in formation of elevated epitaxial layer EEL can be suppressed.

In extension implantation into bulk region BUR, in SOI region SLR, the entire dummy element formation region SDSR is covered with dummy gate electrode SDGE and element formation region SSR is covered with photoresist PR7. Thus, the silicon layer located in the SOI region can be prevented from becoming amorphous, and abnormal growth of the epitaxial layer in formation of the elevated epitaxial layer can be suppressed.

Furthermore, by forming photoresist PR7 as a photoresist preventing extension implantation, a residue of the photoresist in the SOI region can be suppressed, which will be described. When an impurity is implanted into a photoresist formed as an implantation mask in extension implantation, the surface of the photoresist is cured. Therefore, the photoresist may remain without being completely removed in removal of the photoresist. This tendency is more significant with increase in area of the region where the photoresist is formed.

In SOI region SLR in the semiconductor device described above, dummy gate electrode SDGE is arranged to cover the entire dummy element formation region SDSR. Therefore, as a photoresist formed at the time of extension implantation into the bulk region, photoresist PR7 covering element formation region SSR and a region in the vicinity thereof in SOI region SLR, instead of covering the entire SOI region SLR, is formed. Thus, an area of a region in SOI region SLR where a photoresist is formed can be reduced and a residue of the photoresist can be suppressed.

Other than the above, in the semiconductor device described above, elimination of the buried oxide film exposed at the sidewall of the step between SOI region SLR and bulk region BUR in a subsequent step and separation of a portion of the silicon layer located thereon as a foreign substance as described previously can be suppressed.

### Third Embodiment

Here, a technique for exposing an isolation insulating film of an isolation region along the entire perimeter of a sidewall of a step between an SOI region and a bulk region and covering a dummy element formation region arranged in the SOI region with a dummy gate electrode and a sidewall protection film will be described. The same member as in the first embodiment has the same reference character allotted and description thereof will not be repeated unless it is necessary.

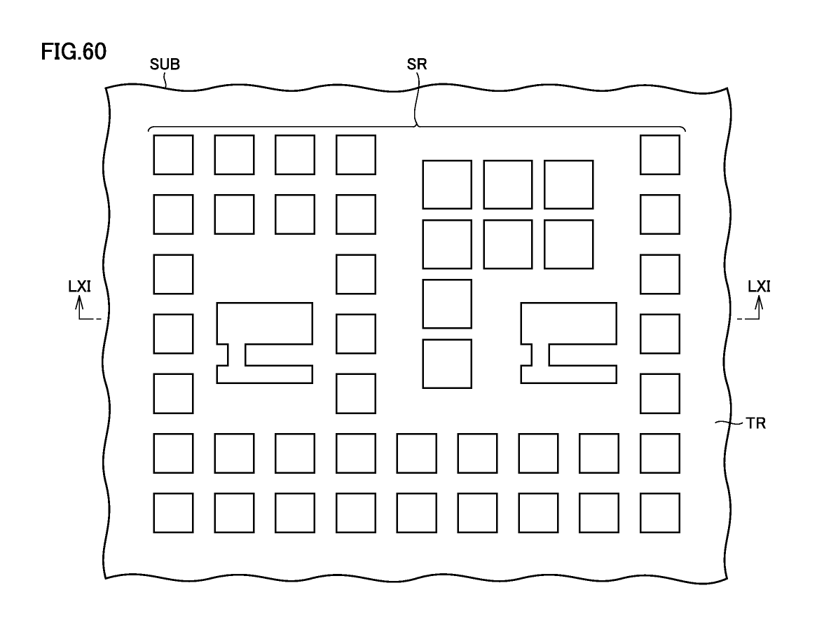

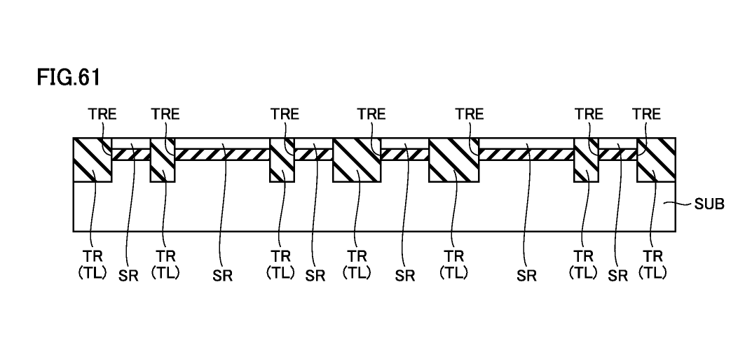

Initially, as shown in FIGS. 60 and 61, isolation region TR is formed in SOI substrate SUB through the process the same as the process shown in FIGS. 2 to 4. Isolation region TR defines element formation region SR. Element formation region SR includes an element formation region where a prescribed semiconductor element is to be formed and a dummy element formation region.

Then, the SOI region and the bulk region are formed through the process the same as the process shown in FIGS. 5 and 6. In bulk region BUR, remaining isolation region TR defines element formation region BSR where a bulk transistor is to be formed and dummy element formation region BDSR. In SOI region SLR, isolation region TR defines element formation region SSR where an SOI transistor is to be formed and dummy element formation region SDSR (see FIGS. 5 and 6).

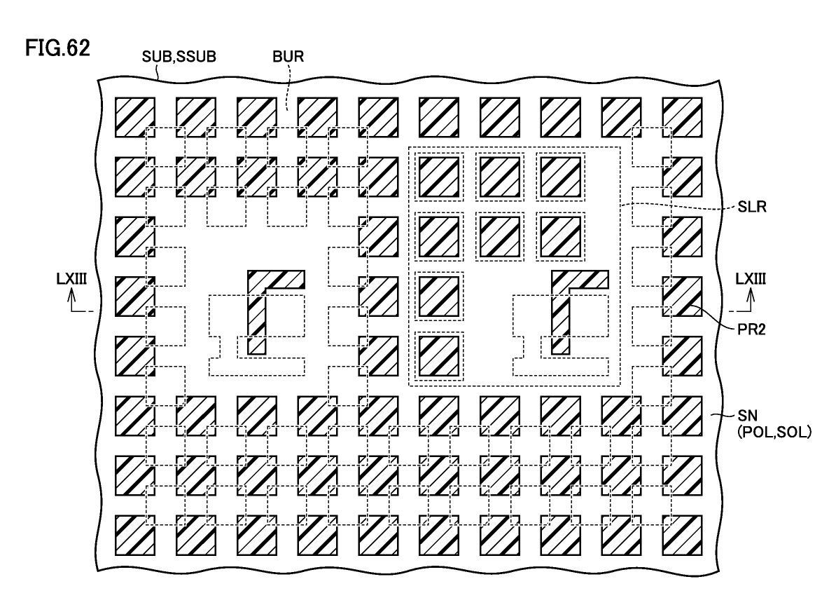

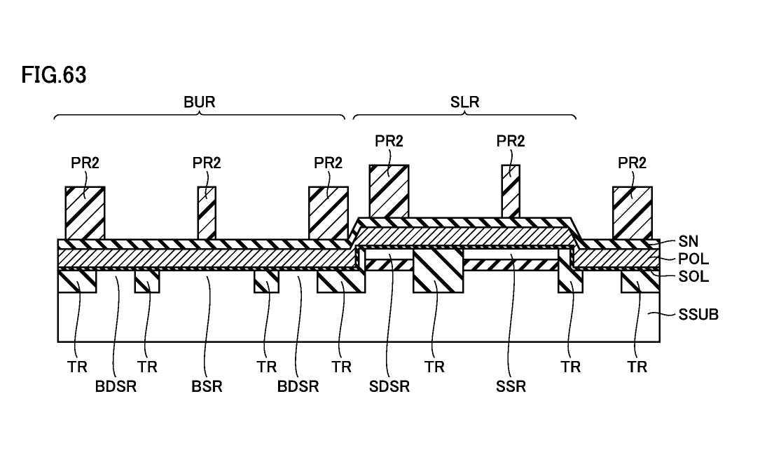

Then, a gate electrode (a gate interconnection) is formed. As shown in FIGS. 62 and 63, silicon oxide film SOL, polysilicon film POL, and silicon nitride film SN are successively formed through the process the same as the process shown in FIGS. 7 and 8. Then, photoresist PR2 for patterning a gate electrode is formed through prescribed photolithography. Here, photoresist PR2 is formed in SOI region SLR such that a patterned dummy gate electrode and a sidewall insulating film which will be described later cover the entire single dummy element formation region SDSR. Namely, photoresist PR2 is formed such that the patterned dummy gate electrode (size) is smaller than dummy element formation region SDSR (size).

Then, a hard mask for patterning a gate electrode is formed through etching treatment onto exposed silicon nitride film SN with photoresist PR2 serving as an etching mask. A gate electrode is formed through etching treatment with the hard mask serving as an etching mask. Thereafter, photoresist PR2 is removed.

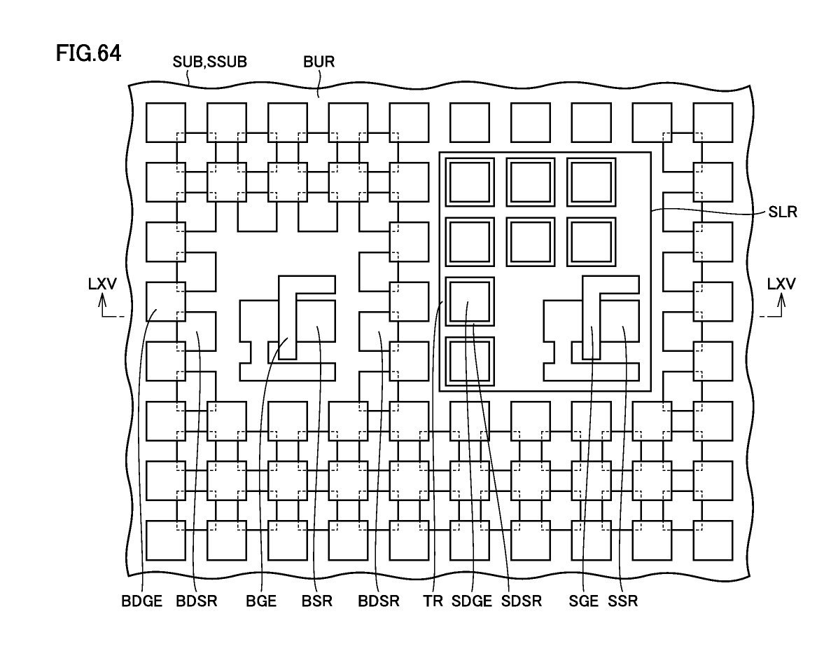

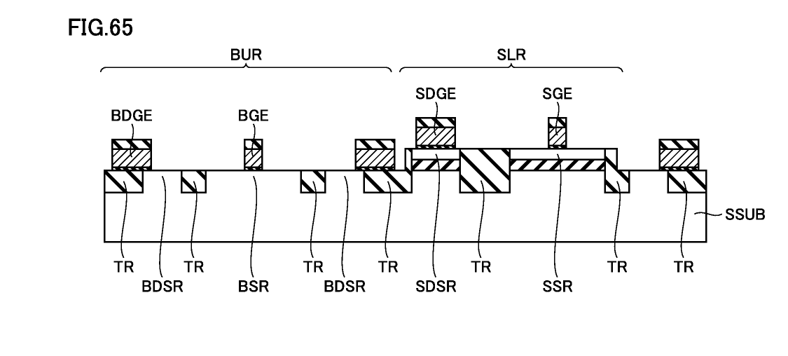

Thus, as shown in FIGS. 64 and 65, gate electrode SGE and dummy gate electrode SDGE are formed in SOI region SLR. Gate electrode SGE is arranged to extend across element formation region SSR. Dummy gate electrode SDGE is arranged to cover dummy element formation region SDSR, so as to expose a portion of dummy element formation region SDSR which is located along an outer perimeter. Gate electrode BGE and dummy gate electrode BDGE are formed in bulk region BUR. Gate electrode BGE is arranged to extend across element formation region BSR.

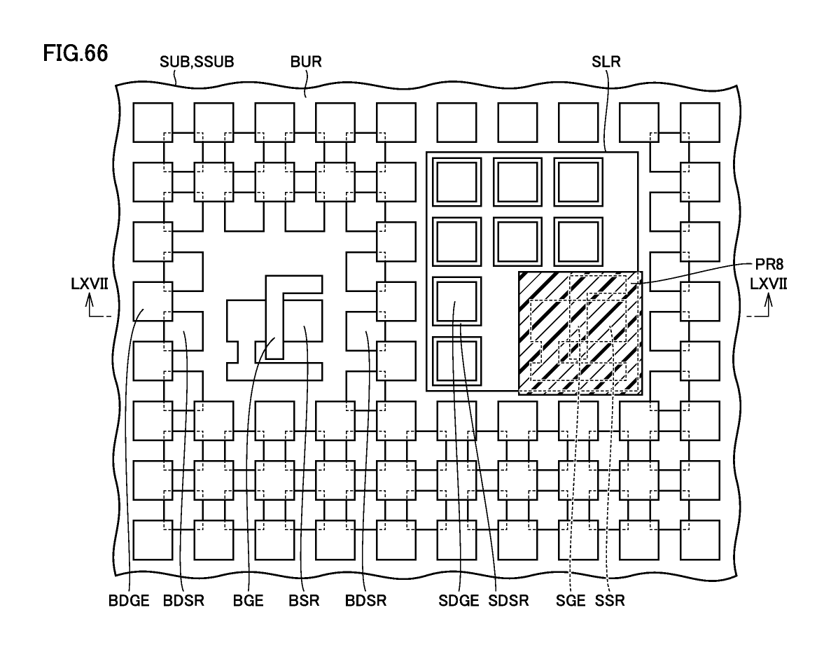

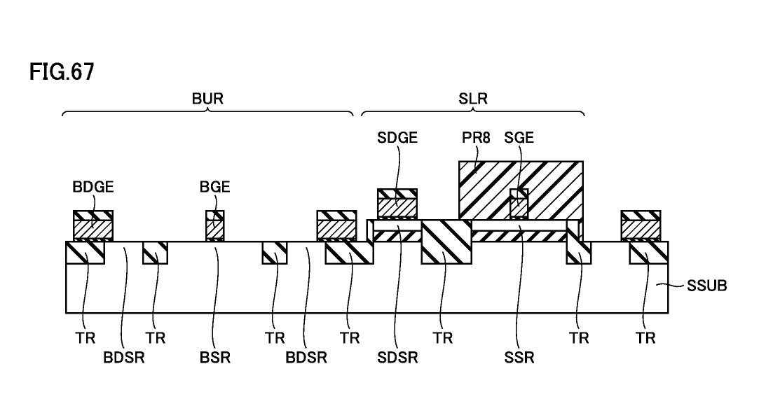

Then, extension implantation of the bulk transistor is carried out. Here, description will be given, assuming an n-channel type bulk transistor as a bulk transistor shown in the drawings. As shown in FIGS. 66 and 67, a photoresist PR8 is formed through prescribed photolithography.

Here, photoresist PR8 covering element formation region SSR and a region in the vicinity thereof in SOI region SLR is formed in SOI region SLR. Therefore, an impurity for extension implantation is implanted into a portion of dummy element formation region SDSR which is not covered with dummy gate electrode SDGE and located along the outer perimeter of dummy element formation region SD SR (a region A), however, this region A will be covered with a sidewall insulating film as will be described later. Therefore, abnormal growth of an epitaxial layer can be prevented. Photoresist PR8 is formed to cover also a region where a p-channel type bulk transistor (not shown) is to be formed.

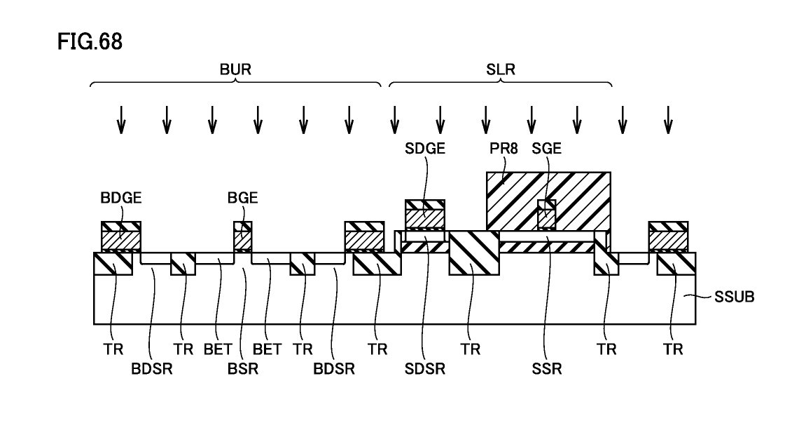

Then, as shown in FIG. 68, extension region BET is formed in element formation region BSR by implanting an impurity into an n-type region with photoresist PR8 serving as an implantation mask. As described already, an impurity into the n-type region is exemplified by nitrogen (N₂), arsenic (As), and phosphorus (P). In particular, in a case of nitrogen (N₂), a concentration of doping therewith is set approximately to 1×10²⁰ cm⁻³. Thereafter, photoresist PR8 is removed. Then, extension implantation of a p-channel type bulk transistor (not shown) is carried out.

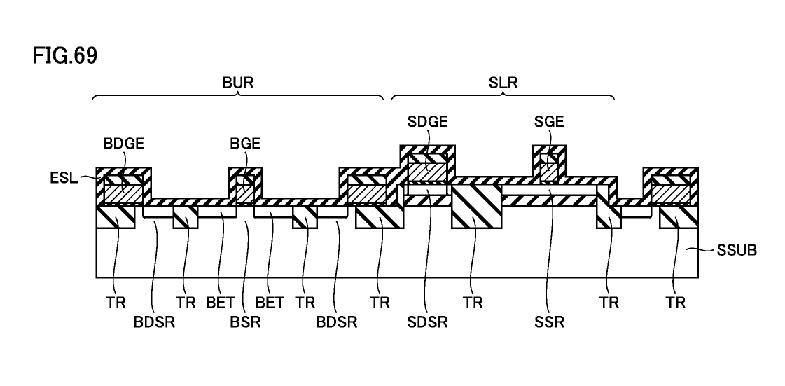

Then, a film preventing an epitaxial layer from being formed in a region other than a prescribed region is formed. As shown in FIG. 69, silicon nitride film ESL is formed to cover gate electrodes SGE and BGE and dummy gate electrodes SDGE and BDGE through the process the same as the process shown in FIG. 14.

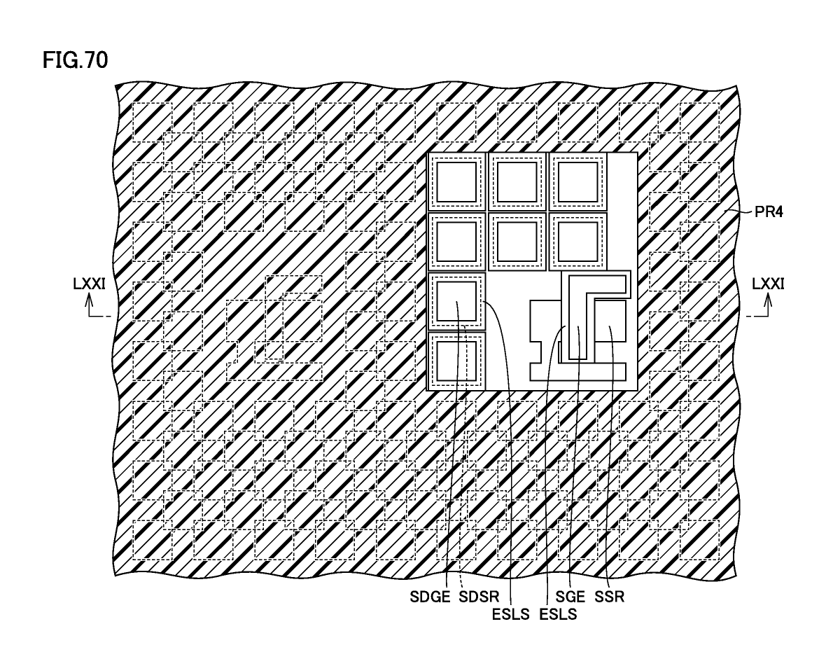

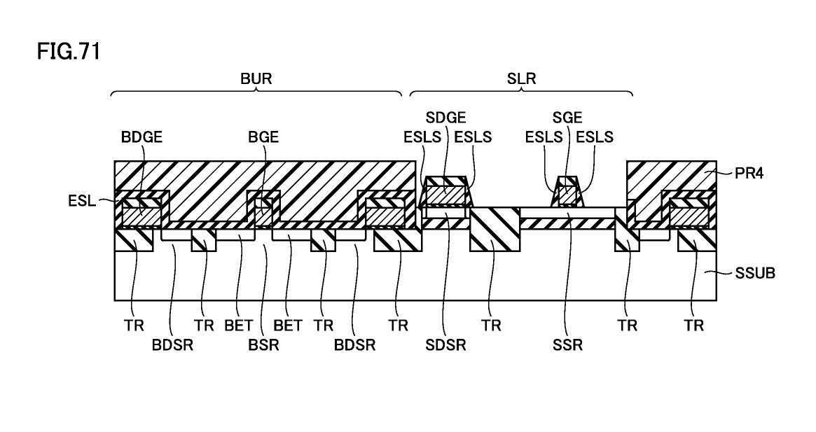

Then, as shown in FIGS. 70 and 71, photoresist PR4 exposing SOI region SLR and covering bulk region BUR is formed through prescribed photolithography through the process shown in FIGS. 15 and 16. Then, a portion of silicon layer SL located in element formation region SSR where an elevated epitaxial layer is to be formed is exposed through anisotropic etching treatment onto exposed silicon nitride film ESL with photoresist PR4 serving as an etching mask.

Here, silicon nitride film ESL remains as sidewall protection film ESLS on the sidewall of gate electrode SGE. In addition, silicon nitride film ESL also remains as sidewall protection film ESLS on the sidewall of dummy gate electrode SDGE. A portion exposed along the outer perimeter of dummy element formation region SDSR is covered with this sidewall protection film ESLS. Thus, a single dummy element formation region SDSR is covered with dummy gate electrode SDGE and sidewall protection film ESLS. Thereafter, photoresist PR4 is removed.

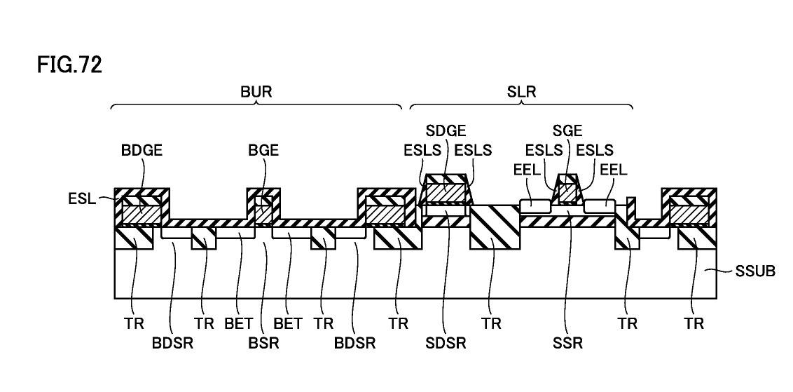

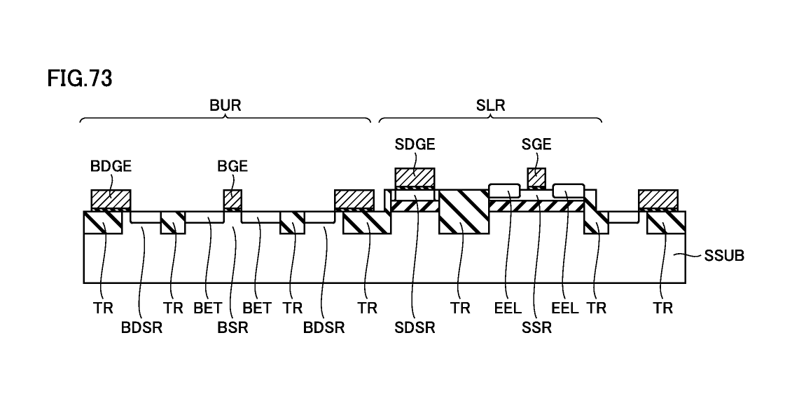

Then, as shown in FIG. 72, elevated epitaxial layer EEL is formed in exposed element formation region SSR with the epitaxial growth method. Then, as shown in FIG. 73, sidewall protection film ESLS is removed through prescribed wet etching treatment after the process the same as the process shown in FIG. 18.

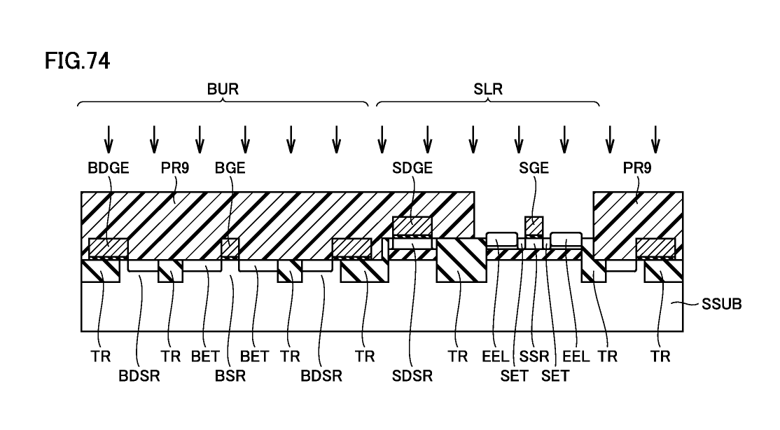

Then, as shown in FIG. 74, a photoresist PR9 exposing element formation region SSR in SOI region SLR and covering another region including bulk region BUR is formed through prescribed photolithography. Then, extension region SET is formed in element formation region SSR by implanting an n-type impurity with photoresist PR9 serving as an implantation mask. Thereafter, photoresist PR9 is removed.

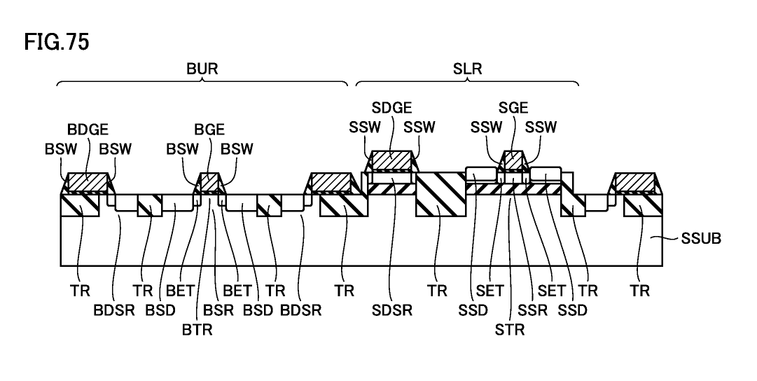

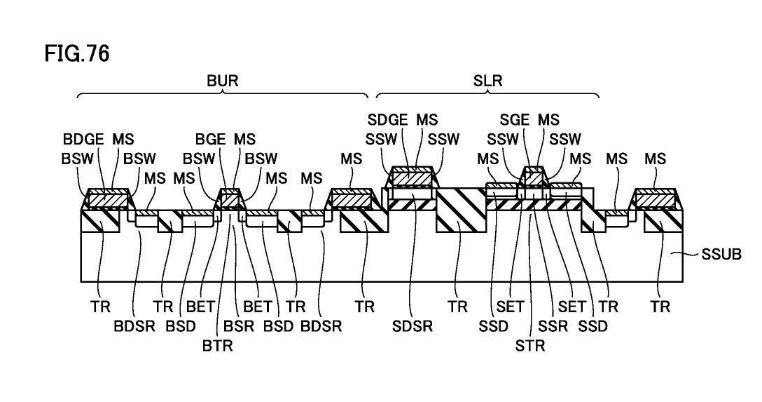

Then, through the process the same as the process shown in FIGS. 22 and 23, sidewall film SSW is formed on the sidewall of each of gate electrode SGE and dummy gate electrode SDGE in SOI region SLR, and sidewall film BSW is formed on the sidewall of each of gate electrode BGE and dummy gate electrode BDGE in bulk region BUR (see FIG. 75). Then, as shown in FIG. 75, through the process the same as the process shown in FIG. 24, source-drain region SSD is formed in SOI region SLR and source-drain region BSD is formed in bulk region BUR. Thus, SOI transistor STR is formed in SOI region SLR, and bulk transistor BTR is formed in bulk region BUR. Then, as shown in FIG. 76, metal silicide film MS is formed through the process the same as the process shown in FIG. 25.

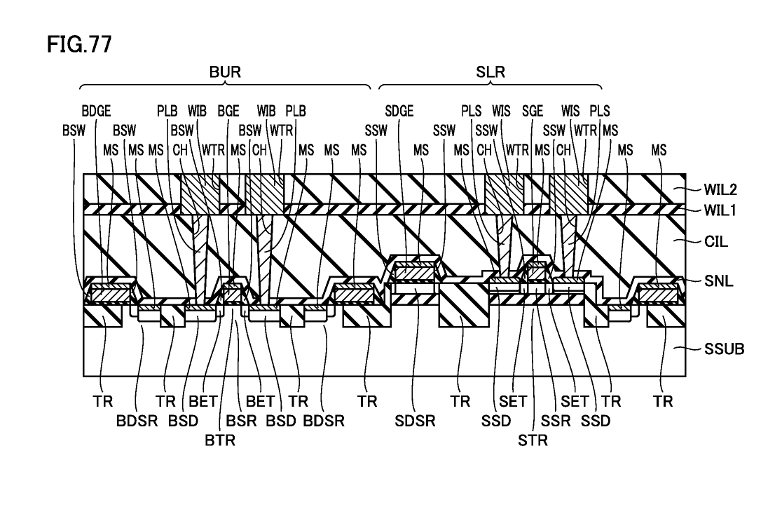

Then, silicon nitride film SNL and contact interlayer insulating film CIL are formed through the process the same as the process shown in FIG. 26 (see FIG. 77). Then, contact plugs PLS and PLB are formed in contact holes CH through the process the same as the process shown in FIG. 27 (see FIG. 77). Then, interconnection interlayer insulating film WIL1 and interconnection interlayer insulating film WIL2 are formed through the process the same as the process shown in FIG. 28 (see FIG. 77). Then, interconnection groove WTR is formed through the process the same as the process shown in FIG. 29 (see FIG. 77).

Then, as shown in FIG. 77, interconnection WIS is formed in SOI region SLR and interconnection WIB is formed in bulk region BUR through the process the same as the process shown in FIG. 30. Thereafter, as necessary, an upper interlayer insulating film and an interconnection (neither of which is shown) are formed. Thus, a main portion of a semiconductor device including an SOI transistor and a bulk transistor is completed.

In the semiconductor device described above, isolation region TR (trench isolation insulating film TL) is exposed along the entire perimeter of the sidewall of the step between SOI region SLR and bulk region BUR. Thus, abnormal growth of an epitaxial layer in SOI region SLR in formation of elevated epitaxial layer EEL can be suppressed.

In extension implantation into bulk region BUR, in SOI region SLR, a most part of dummy element formation region SDSR is covered with dummy gate electrode SDGE, and a portion located along the outer perimeter of remaining exposed dummy element formation region SDSR is covered with sidewall protection film ESLS before formation of elevated epitaxial layer EEL. Thus, even when an impurity is implanted during extension implantation into a portion of the silicon layer in exposed dummy element formation region SDSR and that portion becomes amorphous, abnormal growth of the epitaxial layer during formation of the elevated epitaxial layer can be suppressed.

Furthermore, by forming photoresist PR8 covering element formation region SSR as a photoresist preventing extension implantation, an area of a region where a photoresist is formed can be smaller than in a case that the entire SOI region SLR is covered with a photoresist. Thus, a residue of the photoresist can be suppressed as described previously.

Other than the above, in the semiconductor device described above, elimination of the buried oxide film exposed at the sidewall of the step between SOI region SLR and bulk region BUR in a subsequent step and separation of a portion of the silicon layer located thereon as a foreign substance can be suppressed as described already. A film type (a material) of an insulating film or a conductive film shown in the first to third embodiments is by way of example, and limitation to such a film type is not intended.

### Fourth Embodiment

### First Example

In a first example, a technique for creating a pattern of an element formation region and a gate electrode (a mask pattern) not to arrange a dummy element formation region and a dummy gate electrode at a boundary between an SOI region and a bulk region will be described.

Initially, as shown in FIG. 1, in a step FE, a pattern of each of an element formation region, an isolation region, an SOI region, and a gate electrode is set (obtained) in advance. That step FE will be described in detail.

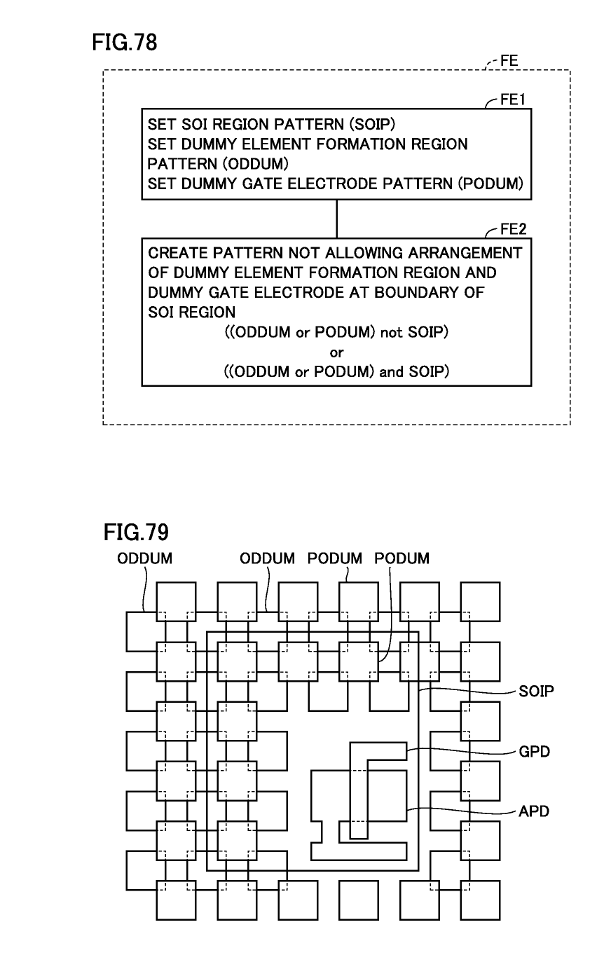

As shown in FIG. 78, in a step FE1, an SOI region pattern SOIP, a dummy element formation region pattern ODDUM, and a dummy gate electrode pattern PODUM registered in advance in a library are set (obtained).

FIG. 79 shows SOI region pattern SOIP, dummy element formation region pattern ODDUM, and dummy gate electrode pattern PODUM in an initial state on the same plane. FIG. 79 also shows together, an element formation region pattern APD where an SOI transistor is to be formed and a pattern of a gate electrode GPD of an SOI transistor. As shown in FIG. 79, in this initial state, dummy element formation region pattern ODDUM and dummy gate electrode pattern PODUM lying across the boundary of SOI region pattern SOIP are present.

Then, in a step FE2, processing for not allowing arrangement of dummy element formation region pattern ODDUM and dummy gate electrode pattern PODUM at the boundary of SOI region pattern SOIP is performed.

(Processing for Dummy Element Formation Region Pattern)

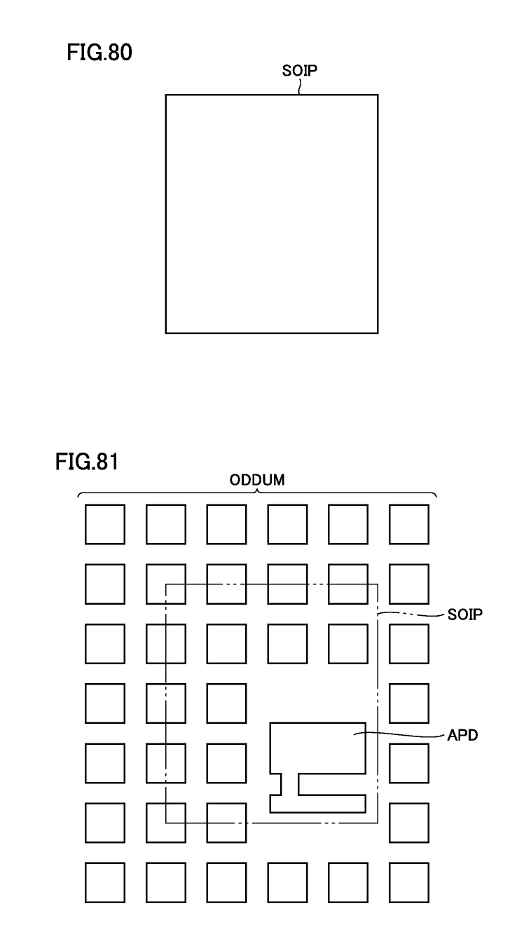

Initially, processing for the dummy element formation region pattern will be described. FIG. 80 shows SOI region pattern SOIP and FIG. 81 shows dummy element formation region pattern ODDUM. As shown in FIG. 81, dummy element formation region pattern ODDUM located across the boundary of SOI region pattern SOIP is present along the boundary.

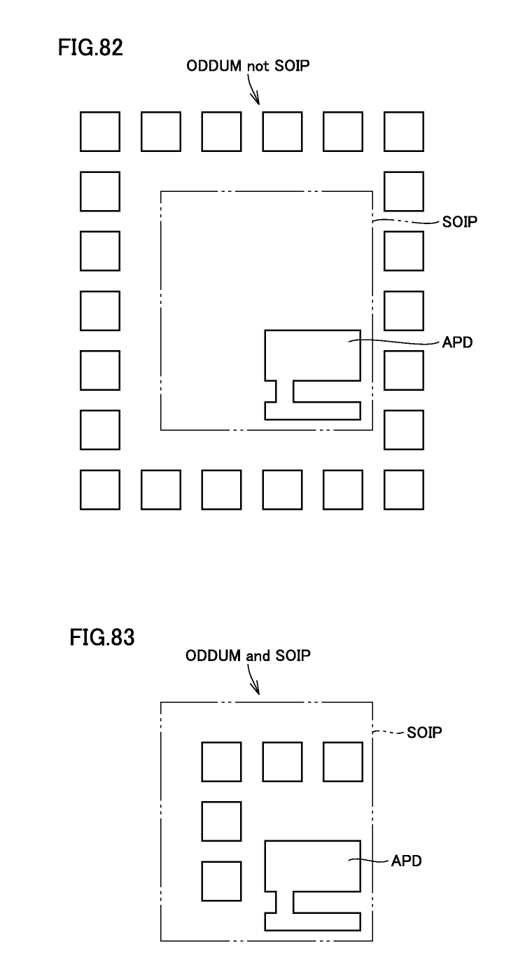

Then, dummy element formation region pattern ODDUM obtained by excluding dummy element formation region pattern ODDUM located within a region of SOI region pattern SOIP and dummy element formation region pattern ODDUM located across the boundary of SOI region pattern SOIP as shown in FIG. 82 from dummy element formation region pattern ODDUM shown in FIG. 81 is created (extracted). This processing is represented by an operational expression below.

ODDUM not SOIP

Then, dummy element formation region pattern ODDUM located within the region of SOI region pattern SOIP is created (extracted) as shown in FIG. 83 from dummy element formation region pattern ODDUM shown in FIG. 81. This processing is represented by an operational expression below.

ODDUM and SOIP

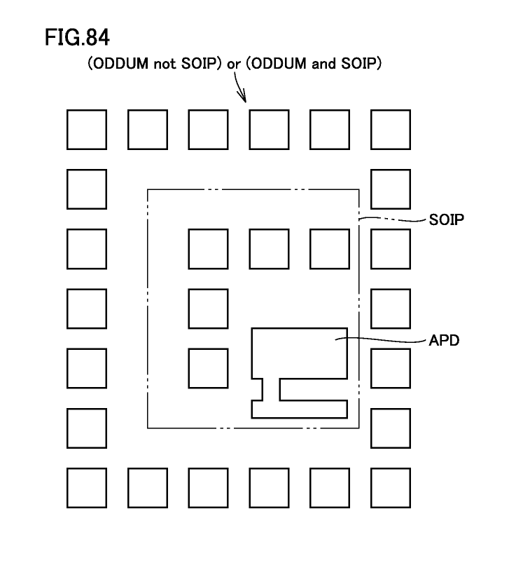

Then, dummy element formation region pattern ODDUM obtained by excluding dummy element formation region pattern ODDUM lying across the boundary of SOI region pattern SOIP is created as shown in FIG. 84, by performing processing for combining dummy element formation region pattern ODDUM shown in FIG. 82 and dummy element formation region pattern ODDUM shown in FIG. 83 with each other. This processing is represented by an operational expression below.

(ODDUM not SOIP) or (ODDUM and SOIP)

In forming an isolation region, a photoresist is formed through photolithography with the use of a photomask manufactured based on dummy element formation region pattern ODDUM shown in FIG. 84 and element formation region pattern APD. Then, trench isolation groove TRE in the isolation region defining the element formation region including the dummy element formation region is formed through prescribed etching treatment with the photoresist serving as an etching mask (see FIGS. 3 and 4).

(Processing for Dummy Gate Electrode Pattern)

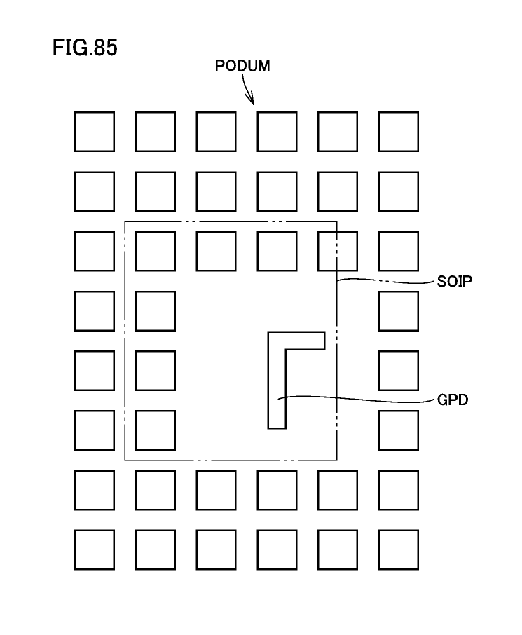

Processing for the dummy gate electrode pattern will now be described. FIG. 85 shows dummy gate electrode pattern PODUM. As shown in FIG. 85, dummy gate electrode pattern PODUM located across the boundary of SOI region pattern SOIP is present.

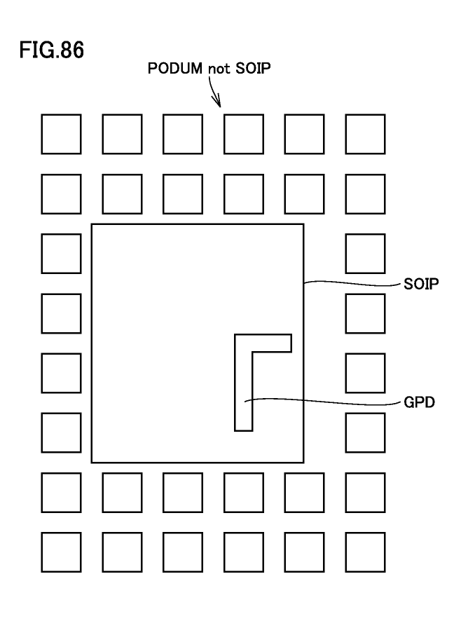

Then, dummy gate electrode pattern PODUM obtained by excluding dummy gate electrode pattern PODUM located within the region of SOI region pattern SOIP and dummy gate electrode pattern PODUM located across the boundary of SOI region pattern SOIP as shown in FIG. 86 from dummy gate electrode pattern PODUM shown in FIG. 85 is created (extracted). This processing is represented by an operational expression below.

PODUM not SOIP

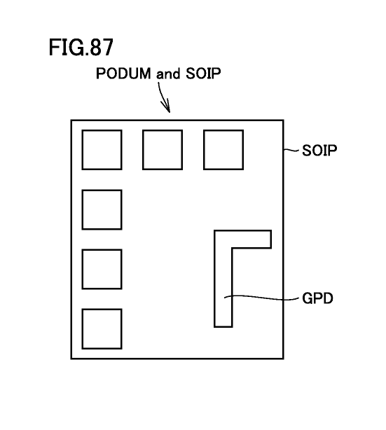

Then, dummy gate electrode pattern PODUM located within the region of SOI region pattern SOIP as shown in FIG. 87 is created (extracted) from dummy gate electrode pattern PODUM shown in FIG. 85. This processing is represented by an operational expression below.

PODUM and SOIP

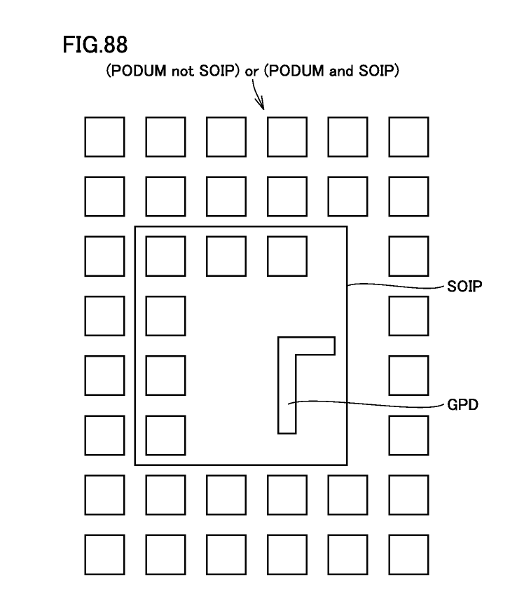

Then, dummy gate electrode pattern PODUM obtained by excluding dummy gate electrode pattern PODUM lying across the boundary of SOI region pattern SOIP is created as shown in FIG. 88, by performing processing for combining dummy gate electrode pattern PODUM shown in FIG. 86 and dummy gate electrode pattern PODUM shown in FIG. 87 with each other. This processing is represented by an operational expression below.

(PODUM not SOIP) or (PODUM and SOIP)

In forming a gate electrode and a dummy gate electrode, photoresist PR2 is formed through photolithography with the use of a photomask manufactured based on dummy gate electrode pattern PODUM shown in FIG. 88 and gate electrode pattern GPD (see FIGS. 7 and 8). Then, gate electrodes SGE and BGE and dummy gate electrodes SDGE and BDGE are formed through prescribed etching treatment with that photoresist PR2 serving as an etching film (see FIGS. 9 and 10).

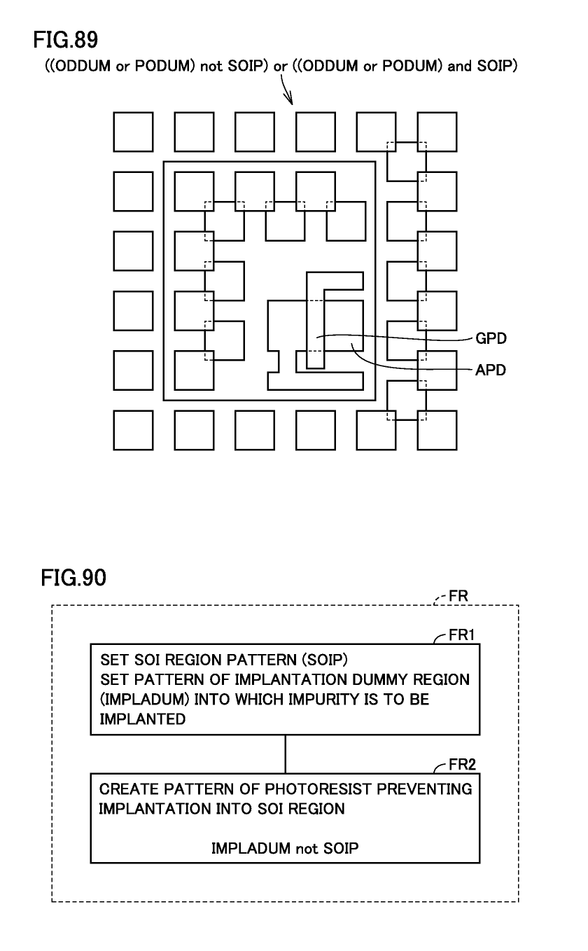

By combining processing for the element formation region pattern and processing for the gate electrode pattern described above, such a pattern that a dummy element formation region and a dummy gate electrode are not arranged at a boundary between the SOI region and the bulk region is created as shown in FIG. 89. This processing is represented by an operational expression below.

((ODDUM or PODUM) not SOIP) or ((ODDUM or PODUM) and SOIP)

### Second Example

In a second example, a technique for creating a pattern of a photoresist preventing implantation of an impurity such that an impurity is not implanted into an SOI region in extension implantation into a bulk region will be described.

Initially, as shown in FIG. 1, a pattern of a photoresist for preventing implantation of an impurity is set (obtained) in advance in a step FR. That step FR will be described in detail.

As shown in FIG. 90, in a step FR1, SOI region pattern SOIP and a pattern IMPLADUM of an implantation dummy region as a region where an impurity for extension implantation is to be implanted, which are registered in advance in a library, are set (obtained).

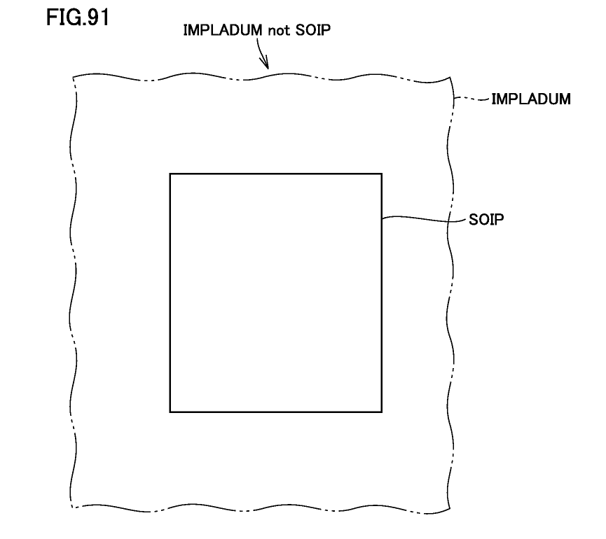

FIG. 91 shows SOI region pattern SOIP and implantation dummy region pattern IMPLADUM in the initial state on the same plane. Then, in a step FR2, a pattern preventing implantation of an impurity into the SOI region is created. Namely, processing for excluding SOI region pattern SOIP from pattern IMPLADUM of an implantation dummy region into which an impurity is to be implanted is performed. This processing is represented by an operational expression below.

IMPLADUM not SOIP

In extension implantation of a bulk transistor, photoresist PR3 is formed through photolithography with the use of a photomask manufactured based on the pattern shown in FIG. 91 (see FIGS. 11 and 12). Then, extension region BET is formed in bulk region BUR while implantation of an impurity into SOI region SLR is prevented by carrying out extension implantation with that photoresist PR3 serving as an implantation mask (see FIG. 13).

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method of manufacturing a semiconductor device, comprising processes of:
preparing a substrate portion having a semiconductor layer formed on a surface of a semiconductor substrate with an insulating layer being interposed;
forming an isolation region in said substrate portion;
defining a first region and a second region adjacent to each other with respect to said substrate portion, and forming a first element formation region and a first dummy element formation region in said first region and forming a second element formation region and a second dummy element formation region in said second region by exposing said semiconductor substrate and said isolation region by allowing said semiconductor layer and said insulating layer located in said first region to remain and removing said semiconductor layer and said insulating layer located in said second region;
forming a first gate electrode and a first dummy gate electrode in said first region and forming a second gate electrode and a second dummy gate electrode in said second region;
forming a cover portion covering said first element formation region and said first dummy element formation region;
introducing an impurity of one conductivity type into said second element formation region in said second region with at least said cover portion serving as a mask after said cover portion is formed; and
forming an elevated epitaxial layer in said first element formation region with an epitaxial growth method,
in said process of forming an isolation region, said isolation region being formed such that said isolation region is exposed along an entire step formed at a boundary between said first region and said second region by removing said semiconductor layer and said insulating layer located in said second region.

2. The method of manufacturing a semiconductor device according to claim 1, wherein
in said process of forming a cover portion, a photoresist is formed as said cover portion so as to cover entire said first region including said first element formation region and said first dummy element formation region.

3. The method of manufacturing a semiconductor device according to claim 1, wherein
in said process of forming a cover portion, said first dummy gate electrode covering entire said first dummy element formation region and a photoresist covering entire said first element formation region are formed as said cover portion, and
in said process of forming an elevated epitaxial layer, said elevated epitaxial layer is formed while said entire first dummy element formation region is covered with said first dummy gate electrode.

4. The method of manufacturing a semiconductor device according to claim 1, having a process of forming a sidewall protection film on a sidewall of each of said first gate electrode and said first dummy gate electrode before said process of forming an elevated epitaxial layer, wherein
in said process of forming a cover portion, said first dummy gate electrode covering entire said first dummy element formation region and a photoresist covering entire said first element formation region are formed as said cover portion, and
in said process of forming an elevated epitaxial layer, said elevated epitaxial layer is formed while said entire first dummy element formation region is covered with said first dummy gate electrode and said sidewall protection film.

5. The method of manufacturing a semiconductor device according to claim 1, wherein
said process of forming an isolation region includes the steps of
setting as a first pattern, a pattern registered in advance as an element formation region,
setting a second pattern as a pattern corresponding to said first region,
setting as a third pattern, a portion of said first pattern located within a region of said second pattern,
setting as a fourth pattern, a pattern obtained by excluding said third pattern and a portion of said first pattern located at a boundary of said second pattern from said first pattern, and
setting as a fifth pattern, a pattern which is combination of said third pattern and said fourth pattern, and
said isolation region is formed based on said fifth pattern.

6. The method of manufacturing a semiconductor device according to claim 1, wherein
the process of forming a first gate electrode, a first dummy gate electrode, a second gate electrode, and a second dummy gate electrode includes steps of
setting a second pattern as a pattern corresponding to said first region,
setting as a sixth pattern, a pattern registered in advance as a gate electrode,
setting as a seventh pattern, a portion of said sixth pattern located within a region of said second region,
setting as an eighth pattern, a pattern obtained by excluding said seventh pattern and a portion of said sixth pattern located at a boundary of said second pattern from said sixth pattern, and
setting as a ninth pattern, a pattern which is combination of said seventh pattern and said eighth pattern, and
said first gate electrode, said first dummy gate electrode, said second gate electrode, and said second dummy gate electrode are formed based on said ninth pattern.

7. The method of manufacturing a semiconductor device according to claim 2, wherein
said process of forming a cover portion includes steps of
setting as a tenth pattern, a pattern registered in advance as a region into which an impurity is to be introduced,
setting as a second pattern, a pattern corresponding to said first region, and
setting as an eleventh pattern, a pattern obtained by excluding said second pattern from said tenth pattern, and
said photoresist covering said first region is formed based on said eleventh pattern.

8. A semiconductor device, comprising:
a substrate portion including a semiconductor substrate and a semiconductor layer formed on said semiconductor substrate with an insulating layer being interposed;
an isolation region formed in said substrate portion;
a first region and a second region formed in said substrate portion to be adjacent to each other;
a first element formation region and a first dummy element formation region defined in said first region by said isolation region;
a second element formation region and a second dummy element formation region defined in said second region by said isolation region; and
an elevated epitaxial layer including gate electrodes formed in said first region and said second region and formed in said first element formation region,
in said first region, said first element formation region and said first dummy element formation region being formed in said semiconductor layer,
in said second region, said second element formation region and said second dummy element formation region being formed in said semiconductor substrate,
a step corresponding to a thickness of said insulating layer and said semiconductor layer being formed at a boundary between said first region and said second region, and
said isolation region being located to surround said first region along an entire perimeter of said step.

9. The semiconductor device according to claim 8, wherein
the impurity of one conductivity type is introduced into said second element formation region and said impurity includes nitrogen (N).

10. The semiconductor device according to claim 8, wherein
said gate electrode is arranged so as not to lie across said boundary between said first region and said second region.

11. The semiconductor device according to claim 8, wherein
said gate electrode includes
a first gate electrode formed in said first element formation region, and
a first dummy gate electrode formed in said first dummy element formation region, and
entire said first dummy element formation region is covered with said first dummy gate electrode.

12. The semiconductor device according to claim 8, wherein
said gate electrode includes
a first gate electrode formed in said first element formation region, and
a first dummy gate electrode formed in said first dummy element formation region,
a sidewall insulating film is formed on a sidewall of each of said first gate electrode and said first dummy gate electrode, and
entire said first dummy element formation region is covered with said first dummy gate electrode and said sidewall insulating film.
